(19) United States
(12) Patent Application Publication
(10) Pub. No.: US 2026/0353948 A1
(43) Pub. Date: Nov. 5, 2026

(54) ELECTRONIC DEVICE AND MANUFACTURING METHOD OF THE SAME

(71) Applicant: SAMSUNG DISPLAY CO., LTD., YONGIN-SI (KR)

(72) Inventors: DONGHYUN LEE, Yongin-si (KR); YOUN-WOONG KANG, Yongin-si (KR); SI JOON SONG, Yongin-si (KR)

(21) Appl. No.: 19/466,804

(22) Filed: Feb. 2, 2026

(30) Foreign Application Priority Data
Apr. 30, 2025 (KR) 10-2025-0057709

(51) Int. Cl. H10K 59/131; H10K 59/12

(52) U.S. Cl. CPC H10K 59/131; H10K 59/1201

(57) ABSTRACT

An electronic device includes a display panel that displays an image, a circuit board coupled to the display panel, and a metal pattern that electrically connects the display panel to the circuit board. The display panel includes a base layer having a first opening defined therein, an insulating layer that is disposed on the base layer and that has a second opening defined therein to overlap the first opening, and a conductive pattern that is disposed on the insulating layer and that has a conductive opening defined therein to expose at least a portion of an inner surface of the insulating layer that defines the second opening.

### CROSS-REFERENCE TO RELATED APPLICATIONS

This application claims priority under 35 U.S.C. § 119 to Korean Patent Application No. 10-2025-0057709, filed on Apr. 30, 2025, in the Korean Intellectual Property Office, the disclosure of which is incorporated by reference herein in its entirety.

### TECHNICAL FIELD

Embodiments of the present disclosure described herein relate to an electronic device and a manufacturing method thereof, and more particularly, relate to an electronic device with improved reliability and a method for manufacturing the electronic device.

### DISCUSSION OF THE RELATED ART

Multimedia devices, such as a television, a mobile phone, a tablet computer, a car navigation device, and a portable game machine, are may make use of various electronic devices such as display panels. An electronic device may include a display panel that displays an image and a circuit board that is coupled to the display panel that provides a driving signal to the display panel. The display panel includes a display part that displays the image and panel pads disposed on the periphery of the panel to provide driving signals to the display part.

The display part included in the electronic device may include a plurality of pixels that display the image and a driver chip for driving the pixels. The electronic device may further include a sensor for sensing an eternal input and the electronic device may simultaneously display images and sense external input.

### SUMMARY

An electronic device includes a display panel that displays an image, a circuit board coupled to the display panel, and a metal pattern that electrically connects the display panel to the circuit board. The display panel includes a base layer having a first opening defined therein, an insulating layer that is disposed on the base layer and that has a second opening overlapping the first opening, and a conductive pattern that is disposed on the insulating layer and that has a conductive opening defined therein exposing at least a portion of an inner surface of the insulating layer that defines the second opening.

An electronic device includes a display panel that displays an image, a processor that provides image data to the display panel, a circuit board coupled to the display panel, a metal pattern that electrically connects the display panel to the circuit board, a window disposed on the display panel, and a housing that is disposed under the display panel and is coupled to the window and that accommodates the display panel and the circuit board. The display panel includes a base layer having a first opening defined therein, an insulating layer that is disposed on the base layer and that has a second opening defined therein overlapping the first opening, and a conductive pattern that is disposed on the insulating layer and that has a conductive opening defined therein exposing at least a portion of an inner surface of the insulating layer that defines the second opening.

A method for manufacturing an electronic device includes forming a base layer having a first opening defined therein, forming, on the base layer, an insulating layer having a second opening defined therein overlapping the first opening, forming a conductive pattern on the insulating layer, patterning the conductive pattern to form a conductive opening that exposes at least a portion of an inner surface of the insulating layer that defines the second opening, providing a bump electrode of a circuit board in the first opening, and forming a metal pattern in the second opening. The conductive pattern is electrically connected with the bump electrode through the metal pattern.

### BRIEF DESCRIPTION OF THE FIGURES

The above and other objects and features of the present disclosure will become apparent by describing in detail embodiments thereof with reference to the accompanying drawings.

FIG. 1 is s perspective view of an electronic device according to an embodiment of the present disclosure.

FIG. 2 is an exploded perspective view of the electronic device according to an embodiment of the present disclosure.

FIG. 3 is a cross-sectional view of a display device according to an embodiment of the present disclosure.

FIG. 4 is a schematic cross-sectional view of a display module according to an embodiment of the present disclosure.

FIG. 5 is a plan view of a display panel according to an embodiment of the present disclosure.

FIG. 6 is a cross-sectional view of the display module according to an embodiment of the present disclosure.

FIG. 7A is a plan view of an input sensing layer according to an embodiment of the present disclosure.

FIG. 7B is a cross-sectional view of the input sensing layer taken along line II-II’ of FIG. 7A.

FIG. 8 is an enlarged plan view of a portion of the display module according to an embodiment of the present disclosure.

FIG. 9 is a cross-sectional view of the display module taken along line III-III’ of FIG. 8.

FIG. 10 is an enlarged plan view of a non-display area of the display module according to an embodiment of the present disclosure.

FIG. 11 is an enlarged plan view of a portion of the non-display area of FIG. 10.

FIG. 12 is a cross-sectional view of a portion of the display panel taken along line IV-IV’ of FIG. 11.

FIGS. 13A and 13B are cross-sectional views of a portion of the display panel according to embodiments of the present disclosure.

FIG. 14 is an enlarged plan view of a portion of the non-display area of FIG. 10.

FIG. 15 is a cross-sectional view of a portion of the display panel taken along line IV-IV’ of FIG. 14.

FIG. 16 is a cross-sectional view of a portion of the display panel according to an embodiment of the present disclosure.

FIGS. 17A, 17B, 17C, 17D, 17E, 17F, 17G, 17H, and 17I are plan views of conductive patterns according to various embodiments of the present disclosure.

FIGS. 18A and 18B are plan views of conductive patterns according to embodiments of the present disclosure.

FIG. 19 is a block diagram of an electronic device according to an embodiment of the present disclosure.

FIG. 20 illustrates schematic views of electronic devices according to various embodiments of the present disclosure.

FIGS. 21A, 21B, 21C, 21D, 21E, 21F, 21G, 21H, and 21I are views illustrating steps of an electronic device manufacturing method according to an embodiment of the present disclosure.

### DETAILED DESCRIPTION

Various changes can be made to the present disclosure, and various embodiments of the present disclosure may be implemented. Thus, specific embodiments are illustrated in the drawings and described as examples herein. However, it should be understood that the present disclosure is not necessarily to be construed as being limited thereto and covers all modifications, equivalents, and alternatives falling within the spirit and scope of the present disclosure.

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals may refer to identical components throughout the drawings and the disclosure. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. As used herein, the term “and/or” includes all of one or more combinations defined by related components.

Terms such as first, second, and the like may be used to describe various components, but the components should not necessarily be limited by the terms. The terms may be used for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not necessarily preclude the presence or addition of one or more other features, numbers, steps, operations, components, parts, or combinations thereof.

The expression “directly disposed” used herein may mean that there may be no additional layer, film, area, or plate between one portion, such as a layer, a film, an area, or a plate, and another portion. For example, the expression “directly disposed” may mean that two layers or two members are disposed without an additional member, such as an adhesive member, disposed therebetween.

Embodiments of the present disclosure relate to an advanced electronic device, particularly a display device, designed with improved electrical bonding and reliability. The device may include a display panel that shows images and a circuit board that drives the display panel. A metal pattern electrically connects the display panel to the circuit board. The structure of the display panel may include a base layer having a first opening, an insulating layer with a second opening that overlaps the first, and a conductive pattern formed on the insulating layer with a conductive opening. This conductive opening exposes part of the inner surface of the insulating layer, which enables reliable electrical connections and ensuring structural integrity.

The manufacturing method may include forming the openings in the base and insulating layers, depositing the conductive pattern, and then introducing a metal ink into the second opening. During a photocuring step, light penetrates through the conductive opening in the conductive pattern, ensuring that the metal ink is fully exposed and properly sintered into a solid, conductive metal pattern. This process not only establishes electrical connectivity between the bump electrodes of the circuit board and the conductive pattern of the display panel, but also enhances the quality and reliability of the cured metal ink. By allowing light to reach all parts of the ink, the process avoids partial curing, resulting in stronger, more uniform electrical bonds.

Embodiments of the present disclosure provide an electronic device with improved electrical reliability by optimizing the interface between the display panel and its circuit board. The design addresses problems of incomplete curing and bonding failures often seen in conventional structures. Embodiments of the present disclosure may also enable slimmer bezel designs and supports applications in foldable or flexible devices by reducing stress in bonding areas. By combining structural modifications to the display panel with a carefully tailored curing process for the metal ink, embodiments of the present disclosure may enhance both manufacturing efficiency and device performance, making it suitable for a wide range of multimedia and mobile electronic products.

Hereinafter, a display device of an embodiment will be described with reference to the accompanying drawings.

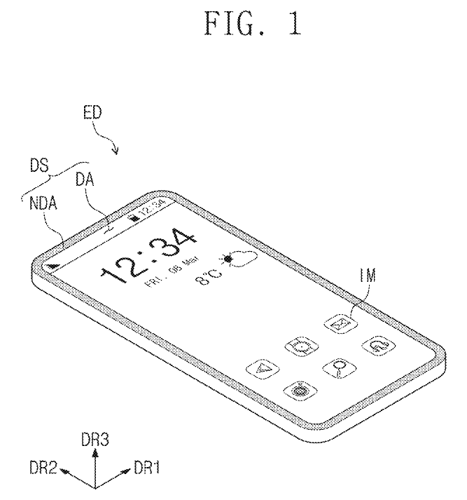

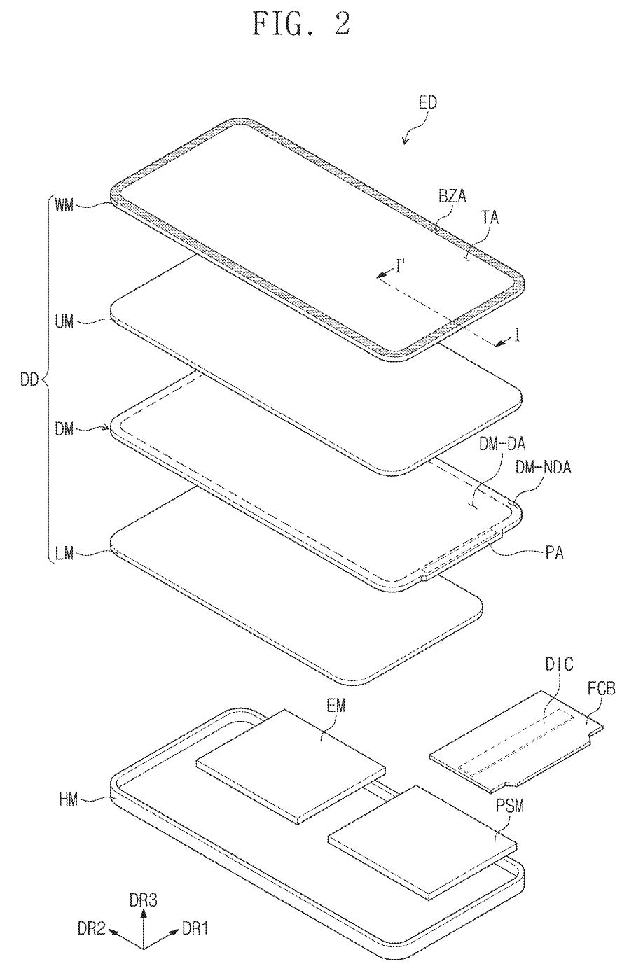

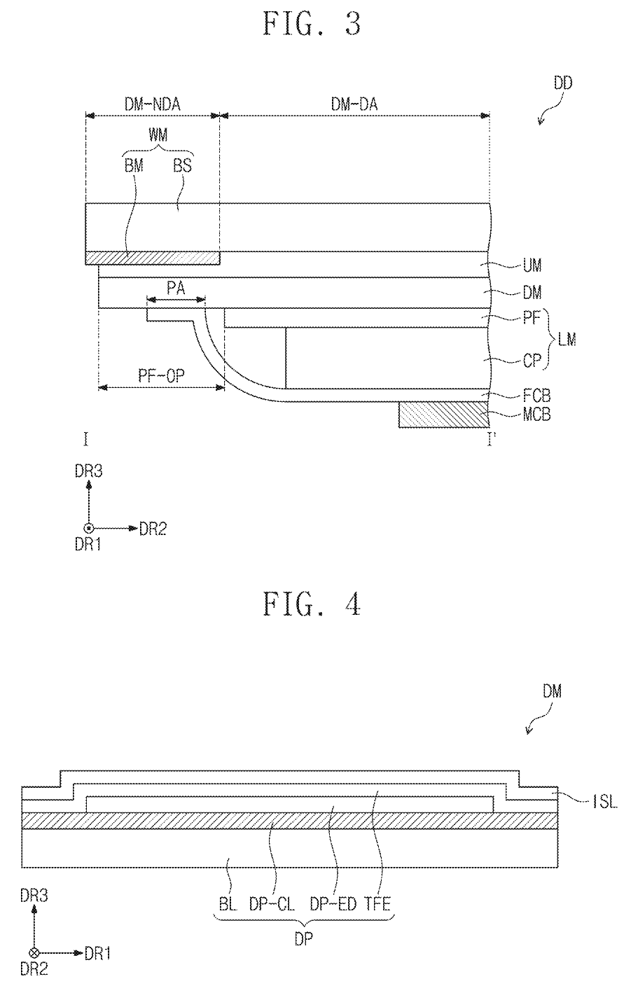

FIG. 1 is a perspective view of an electronic device according to an embodiment of the present disclosure. FIG. 2 is an exploded perspective view of the electronic device according to an embodiment of the present disclosure. FIG. 3 is a cross-sectional view of a display device according to an embodiment of the present disclosure.

Referring to FIG. 1, the electronic device ED, according to an embodiment of the present disclosure, may include a display surface DS defined by a first direction DR1 and a second direction DR2 crossing the first direction DR1. The electronic device ED may provide an image IM to a user through the display surface DS.

The display surface DS may include a display area DA and a non-display area NDA proximate to the display area DA (for example, surrounding the display area DA on at least two sides thereof). The display area DA may be an area that displays the image IM, and the non-display area NDA may be an area that does not display the image IM (for example, by including no pixels). The non-display area NDA may surround the display area DA. However, without being limited thereto, the shape of the display area DA and the shape of the non-display area NDA may be modified.

Hereinafter, a direction substantially perpendicular to a plane defined by the first direction DR1 and the second direction DR2 is defined as a third direction DR3. The third direction DR3 is used as the basis for distinguishing a front surface and a rear surface of each member from each other. The expression "when viewed from above the plane" or “in a plan view” used herein may be defined as a state in which the electronic device ED is viewed in the third direction DR3.

In an embodiment of the present disclosure, the electronic device ED may be a foldable electronic device capable of being folded about a folding axis to at least a noticeable extent without cracking or otherwise sustaining damage thereto. The folding axis may be parallel to the first direction DR1 or the second direction DR2, and a folding area may be defined in a portion of the display area DA. The electronic device ED may be folded in an in-folding manner such that the opposite sides of the display area DA face each other (so that the display area DA is protected when in this state) or may be folded in an out-folding manner such that the opposite sides of the display area DA move away from each other (so that the display area DA remains visible when in this state).

Referring to FIG. 2, the electronic device ED may include a display device DD, an electronic module EM, a power supply module PSM, and a housing HM. Although the electronic device ED is schematically illustrated in FIG. 2, the electronic device ED may further include a mechanical structure (e.g., a hinge) for controlling operation (e.g., folding or rolling) of the display device DD.

The display device DD generates the image IM and senses an external input. The display device DD includes a window WM, an upper member UM, a display module DM, a lower module LM, a circuit board (or, a flexible circuit board) FCB, and a driver chip DIC. The upper member UM includes members disposed over the display module DM, and the lower member LM includes members disposed under the display module DM.

The window WM provides the front surface of the electronic device ED. The window WM includes a transmissive area TA and a bezel area BZA. The display area DA and the non-display area NDA of the display surface DS illustrated in FIG. 1 are defined by the transmissive area TA and the bezel area BZA. The transmissive area TA is an area through which an image passes, and the bezel area BZA is an area that covers a structure/member disposed under the window WM and through which no image passes.

The display module DM includes a display area DM-DA and a non-display area DM-NDA that correspond to the display area DA and the non-display area NDA illustrated in FIG. 1. The expression “one area/portion corresponds to another area/portion” used herein means that the areas/portions overlap each other and is not necessarily limited to the same area.

A pad area PA is disposed on one side of the non-display area DM-NDA. The pad area PA is an area electrically bonded (or, connected) with the circuit board FCB to be described below. In this embodiment, the pad area PA is defined on the rear surface of the display module DM.

The display module DM has a substantially quadrilateral shape. The expression “substantially quadrilateral shape” used herein includes not only a quadrilateral shape in a mathematical sense but also a shape similar to a quadrilateral that can be perceived as a quadrilateral by the user. For example, the substantially quadrilateral shape may include a quadrilateral shape having rounded corner areas. In addition, the substantially quadrilateral shape is not necessarily limited to the fact that the edge of a display panel DP is a straight line, and the edge may include a curved area.

The upper member UM may include a protective film or an optical film. The optical film may include a polarizer and a retarder for reducing reflection of external light. The lower member LM may include a protective film that protects the display panel DP, a support member that supports the display panel DP, and a digitizer. Detailed description of the upper member UM and the lower member LM will be given below.

The circuit board FCB is disposed below the display module DM. The circuit board FCB may be bonded to the rear surface of the display panel DP. The circuit board FCB electrically connects the display panel DP and a main circuit board MCB (refer to FIG. 3). The circuit board FCB includes at least one insulating layer and at least one conductive layer. The conductive layer may include a plurality of signal lines.

The driver chip DIC may be mounted on the circuit board FCB. The driver chip DIC may include a driving circuit for driving pixels of the display panel DP, for example, a data driver circuit. Although FIG. 2 illustrates the structure in which the driver chip DIC is mounted on the circuit board FCB, the present disclosure is not necessarily limited thereto. For example, the driver chip DIC may be mounted on the display module DM or the main circuit board.

The electronic module EM may include a control module, a wireless communication module, an image input module, a sound input module, a sound output module, a memory, and an external interface module. The electronic module EM may include the main circuit board, and the modules may be mounted on the main circuit board or may be electrically connected to the main circuit board through a flexible circuit board. The electronic module EM is electrically connected with the power supply module PSM.

Although not separately illustrated, the electronic device ED may further include an electro-optical module. The electro-optical module may be an electronic component that outputs or receives an optical signal. The electro-optical module may include a camera module and/or a proximity sensor. The camera module may take an external image through a partial area of the display panel DP.

The housing HM illustrated in FIG. 2 is coupled with the display device DD, particularly, the window WM to accommodate the other modules. Although the housing HM is illustrated as having a single-body shape, the housing HM is not necessarily limited thereto. The housing HM may include a plurality of portions (e.g., lateral portions and a bottom portion) coupled with one another.

FIG. 3 is a cross-sectional view of the display device DD taken along line I-I’ of FIG. 2. Referring to FIG. 3, the window WM may include a base substrate BS and a bezel pattern BM disposed on the lower surface of the base substrate BS. The base substrate BS may include a synthetic resin film or a glass substrate. The base substrate BS may have a multi-layer structure. The base substrate BS may include a thin glass substrate, a protective film disposed on the thin glass substrate, and an adhesive layer that couples the thin glass substrate and the protective film.

The bezel pattern BM may be a colored light blocking film and may be formed, for example, by a coating method. The bezel pattern BM may include a base material and a dye or pigment mixed in the base material. The bezel pattern BM overlaps the non-display area NDA illustrated in FIG. 1 and the bezel area BZA illustrated in FIG. 2. The bezel pattern BM may be disposed on the lower surface of the base substrate BS. When the base substrate BS has a multi-layer structure, the bezel pattern BM may be disposed between interfaces defined by a plurality of layers. For example, the bezel pattern BM may be disposed between the thin glass substrate and the protective film. Although not separately illustrated, the window WM may further include, on the upper surface of the base substrate BS, at least one of a hard coating layer, an anti-fingerprint layer, and an anti-reflective layer.

The upper member UM may include an upper film. The upper film may include a synthetic resin film. The synthetic resin film may include polyimide, polycarbonate, polyamide, triacetylcellulose, polymethylmethacrylate, or polyethylene terephthalate.

The upper film may be configured to absorb external impact applied to the front surface of the display device DD. In an embodiment of the present disclosure, the display module DM may include a color filter replacing a polarizing film as an anti-reflective member, and due to this, the impact strength of the front surface of the display device DD may be reduced. The upper film may compensate for the reduced impact strength by applying the color filter.

The upper member UM overlaps the bezel area BZA (refer to FIG. 2) and the transmissive area TA (refer to FIG. 2). The upper member UM may overlap only a partial area of the bezel area BZA. A portion of the bezel pattern BM may be exposed from the upper member UM. In an embodiment of the present disclosure, the upper member UM may be omitted. In an embodiment of the present disclosure, the upper member UM may be replaced with an optical film including a polarizer and a retarder.

The display device DD may further include, between the upper member UM and the window WM, an adhesive layer that couples the upper member UM and the window WM. The adhesive layer may be a pressure sensitive adhesive (PSA) film or an optically clear adhesive (OCA).

The display module DM is disposed under the upper member UM. The display module DM overlaps the bezel area BZA (refer to FIG. 2) and the transmissive area TA (refer to FIG. 2). The display module DM may completely overlap the upper member UM in the bezel area BZA. The side surfaces of the display module DM may be aligned with the side surfaces of the upper member UM, and the corners of the display module DM may be aligned with the corners of the upper member UM when viewed from above the plane.

In the bezel area BZA, the pad area PA of the display module DM may overlap the upper member UM. A portion of the display module DM that corresponds to the pad area PA may be coupled to the lower surface of the upper member UM by an adhesive layer. Since the pad area PA overlaps the upper member UM and the portion of the display module DM that overlaps the pad area PA is coupled to the upper member UM, the upper member UM may sufficiently support the pad area PA when the circuit board FCB is bonded to the pad area PA.

The lower member LM may include a lower film PF and a cover panel CP. In an embodiment of the present disclosure, the lower member LM may further include a support plate and a digitizer.

The lower film PF may expose the pad area PA of the display module DM. The lower film PF may have a smaller size than the display module DM. For example, the lower film PF may overlap only the display area DM-DA of the display module DM. An open area PF-OP corresponding to the non-display area DM-NDA may be defined in the lower film PF. Alternatively, the lower film PF may have a size substantially corresponding to the display module DM. In this case, an open area PF-OP corresponding to the pad area PA may be defined in the lower film PF. The pad area PA may be exposed through the open area PF-OP.

The cover panel CP may be disposed under the lower film PF. The cover panel CP may increase resistance to a compressive force generated by external pressing. Accordingly, the cover panel CP may serve to prevent deformation of the display module DM. The cover panel CP may include a flexible plastic material such as polyimide or polyethylene terephthalate. In addition, the cover panel CP may be a colored film having low light transmittance. The cover panel CP may absorb light incident from the outside. For example, the cover panel CP may be a black synthetic resin film. When the display device DD is viewed from above the window WM, components disposed under the cover panel CP might not be visible to the user.

A support plate may be further disposed under the cover panel CP. The support plate may include a high-strength metallic material. The support plate may include a fiber reinforced composite. The support plate may include reinforced fibers disposed inside a matrix portion. The reinforced fibers may be carbon fibers or glass fibers. The matrix portion may include a polymer resin. The matrix portion may include a thermoplastic resin. For example, the matrix portion may include a polyamide resin or a polypropylene resin. For example, the reinforced fiber composite may be carbon fiber reinforced plastic (CFRP) or glass fiber reinforced plastic (GFRP).

The main circuit board MCB may be disposed on the lower surface of the circuit board FCB. The circuit board FCB may include an insulating film and conductive wiring mounted on the insulating film. The main circuit board MCB may include signal lines and electronic elements. The electronic elements may be connected to the signal lines and may be electrically connected with the display module DM. The electronic elements generate various types of electrical signals, for example, a signal for generating an image or a signal for sensing an external input, or process sensed signals. The main circuit board MCB may be singly provided to correspond to each electrical signal to be generated and processed. Three or more main circuit boards may be provided, and the main circuit board MCB is not necessarily limited to any one embodiment.

The main circuit board MCB may include the driver chip DIC (refer to FIG. 2) mounted within the main circuit board MCB.

Referring to FIGS. 2 and 3, the circuit board FCB is coupled to the rear surface of the display panel DP (e.g., rear bonding). Since the non-display area DM-NDA of the display module DM is not bent, a defect occurring when the non-display area DM-NDA of the display panel DP is bent may be prevented. In addition, the area of the bezel area BZA of the window WM for covering the non-display area DM-NDA of the display panel DP may be reduced.

Thus, a foldable electronic device may feature a display surface divided into a display area for images and a surrounding non-display area. The device may have a layered display module including a window, upper and lower members, a circuit board, and a driver chip, with additional elements such as a pad area for electrical bonding, protective films, a cover panel, and optional reinforcements like a support plate. By coupling the circuit board to the rear surface of the display panel, the design may prevent bending defects in the non-display area and may reduce the bezel size, thereby improving durability and enabling slimmer device configurations.

FIG. 4 is a schematic cross-sectional view of the display module according to an embodiment of the present disclosure.

Referring to FIG. 4, the display panel DM may include the display panel DP and an input sensing layer ISL. The display panel DP may include a base layer BL, a circuit layer DP-CL, a light emitting element layer DP-ED, and an encapsulation layer TFE.

The circuit layer DP-CL is disposed on the upper surface of the base layer BL. The base layer BL may be a flexible substrate capable of being bent, folded, or rolled to at least a noticeable extent without cracking or otherwise sustaining damage thereto. The base layer BL may be a glass substrate, a metal substrate, or a polymer substrate. However, embodiments of the present disclosure are not necessarily limited thereto, and the base layer BL may be an inorganic layer, an organic layer, or a composite layer. The base layer BL has substantially the same shape as the display panel DP.

The base layer BL may have a multi-layer structure. For example, the base layer BL may include a first synthetic resin layer, a second synthetic resin layer, and inorganic layers disposed therebetween. Each of the first synthetic resin layer and the second synthetic resin layer may include a polyimide resin, but is not necessarily particularly limited.

The circuit layer DP-CL may be disposed on the base layer BL. The circuit layer DP-CL may include a plurality of insulating layers, a plurality of semiconductor patterns, a plurality of conductive patterns, and signal lines. The circuit layer DP-CL may include a pixel driving circuit. Hereinafter, unless otherwise specified, when component A and component B are disposed on the same layer, it may be interpreted that component A and component B are formed by the same process and include the same material or have the same stack structure. Conductive patterns or semiconductor patterns disposed on the same layer may be interpreted as described above.

The light emitting element layer DP-ED may be disposed on the circuit layer DP-CL. The light emitting element layer DP-ED may include a light emitting element. For example, the light emitting element may include an organic luminescent material, an inorganic luminescent material, an organic-inorganic luminescent material, a quantum dot, a quantum rod, a micro-LED, or a nano-LED.

The encapsulation layer TFE may be disposed on the light emitting element layer DP-ED. The encapsulation layer TFE may protect the light emitting element layer DP-ED, for example, the light emitting element from foreign matter such as moisture, oxygen, and dust particles. The encapsulation layer TFE may include at least one inorganic encapsulation layer and at least one organic encapsulation layer. The encapsulation layer TFE may include a stack structure of a first inorganic encapsulation layer, an organic layer, and a second inorganic encapsulation layer.

The input sensing layer ISL may be directly disposed on the display panel DP. The input sensing layer ISL may sense a user input, for example, by an electromagnetic induction method or a capacitive method. The display panel DP and the input sensing layer ISL may be formed through a continuous process. The expression “directly disposed” used herein may mean that a third component is not disposed between the input sensing layer ISL and the display panel DP. For example, a separate adhesive layer might not be disposed between the input sensing layer ISL and the display panel DP.

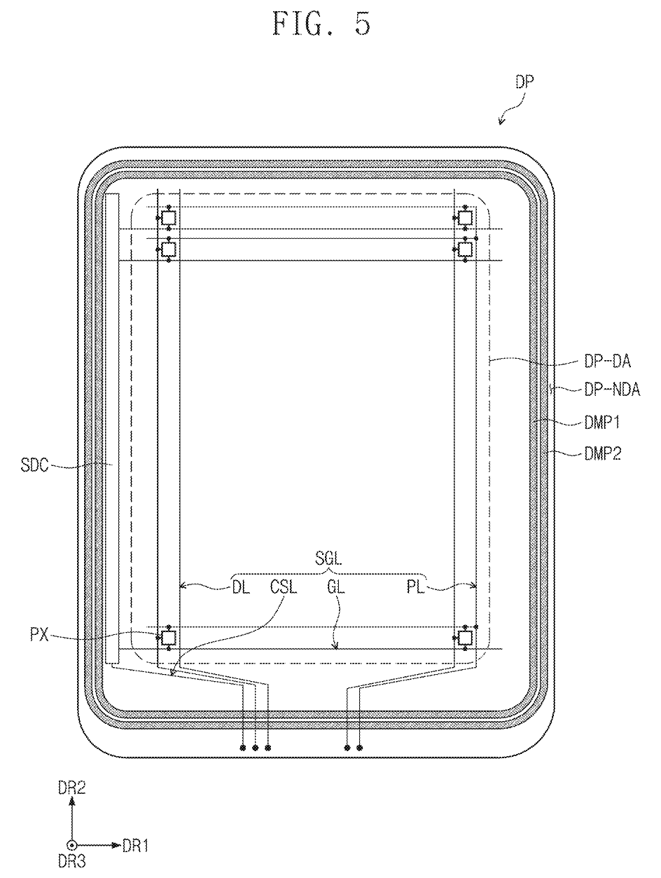

FIG. 5 is a plan view of the display panel according to an embodiment of the present disclosure. FIG. 6 is a cross-sectional view of the display module according to an embodiment of the present disclosure.

As illustrated in FIG. 5, the display panel DP may include a scan driver circuit SDC, a plurality of signal lines SGL, and a plurality of pixels PX. The plurality of pixels PX are disposed in a display area DP-DA. Each of the pixels PX includes a light emitting element and a pixel driving circuit connected thereto. The scan driver circuit SDC, the plurality of signal lines SGL, and the pixel driving circuit may be included in a driving element layer 120 illustrated in FIG. 4.

The scan driver circuit SDC may include a gate driver circuit. The gate driver circuit generates a plurality of scan signals and sequentially outputs the plurality of scan signals to a plurality of scan lines GL to be described below. The scan driver circuit SDC may further include an emission driver circuit distinguished from the gate driver circuit. The emission driver circuit may output scan signals to another group of scan lines.

The scan driver circuit SDC may include a plurality of thin film transistors formed through the same process as the pixel driving circuit, for example, a low temperature polycrystalline silicon (LTPS) process or a low temperature polycrystalline oxide (LTPO) process.

The plurality of signal lines SGL include the scan lines GL, data lines DL, a power line PL, and a control signal line CSL. Each of the scan lines GL is connected to a corresponding pixel PX among the plurality of pixels PX, and each of the data lines DL is connected to a corresponding pixel PX among the plurality of pixels PX. The power line PL is connected to the plurality of pixels PX. The data lines DL provide data signals to the pixels PX. The control signal line CSL may provide control signals to the scan driver circuit SDC.

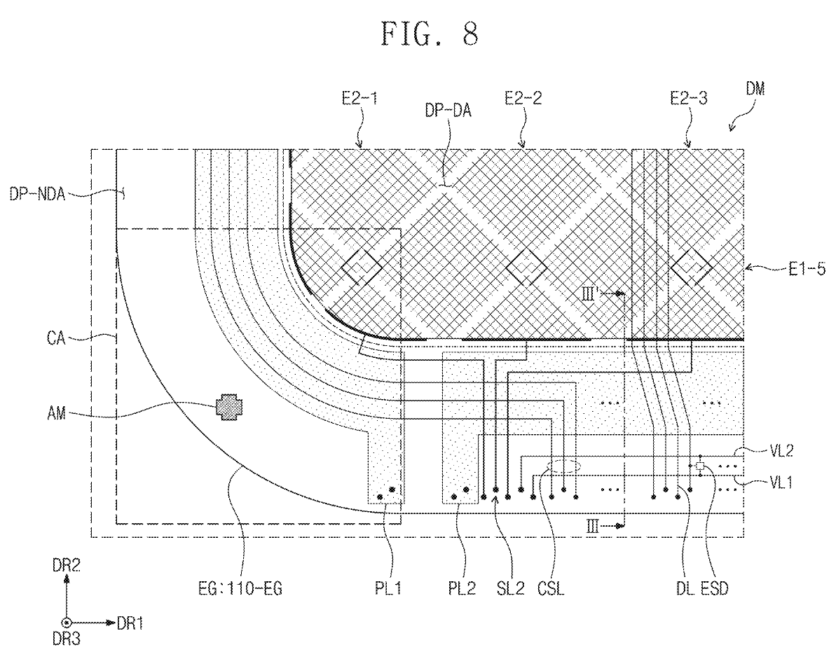

As illustrated in FIG. 8, the power line PL may include a first power line PL1 that receives a first power supply voltage and a second power line PL2 that receives a second power supply voltage having a higher level than the first power supply voltage. The first power supply voltage is provided to the pixels PX through the first power line PL1, and the second power supply voltage is provided to the pixels PX through the second power line PL2. Although one control signal line CSL is illustrated as an example in FIG. 5, a plurality of control signal lines CSL may be provided.

The scan lines GL, the data lines DL, and the power line PL may overlap the display area DP-DA and a non-display area DP-NDA, and the control signal line CSL may overlap the non-display area DP-NDA. The ends of the plurality of signal lines SGL may be aligned on one side of the non-display area DP-NDA. Each of the plurality of signal lines SGL may have a single-body shape, but may include a plurality of portions disposed on different layers. Different portions distinguished from each other by an insulating layer may be connected through a contact hole penetrating the insulating layer. For example, the data lines DL may include a first portion disposed in the display area DP-DA and a second portion disposed in the non-display area DP-NDA and disposed on a layer different from the layer on which the first portion is disposed. The first portion and the second portion may include different materials and may have different stack structures.

The display panel DP may include insulating patterns DMP1 and DMP2. In FIG. 5, the first insulating pattern DMP1 and the second insulating pattern DMP2 are illustrated as an example. The first insulating pattern DMP1 and the second insulating pattern DMP2 are disposed in the non-display area DP-NDA and surround the display area DP-DA. Each of the first insulating pattern DMP1 and the second insulating pattern DMP2 may have a closed-line shape. The first insulating pattern DMP1 and the second insulating pattern DMP2 serve as a dam that prevents a liquid organic material from overflowing in an inkjet process of the display panel DP. Description thereabout will be given below.

FIG. 6 illustrates a cross-section of the display module DM corresponding to the pixel PX of FIG. 5.

A pixel driving circuit PC that drives a light emitting element LD may include a plurality of pixel driving elements. The pixel driving circuit PC may include a plurality of transistors and a capacitor Cst. In FIG. 6, a silicon transistor S-TFT and an oxide transistor O-TFE are illustrated as an example. The pixel driving circuit PC of FIG. 6 is only an embodiment, and the configuration of the pixel driving circuit PC is not necessarily limited thereto. The pixel driving circuit PC may include only one of the silicon transistor S-TFT and the oxide transistor O-TFT.

In an embodiment, a base layer 110 includes a plurality of layers, but is illustrated as a single layer for simplicity. The base layer 110 may include a synthetic resin such as polyimide. The base layer 110 may be formed by coating a working substrate (or, a carrier substrate) with a synthetic resin layer. When the display module DM is completed through a subsequent process, the working substrate may be removed.

Referring to FIG. 6, a barrier layer 10br may be disposed on the base layer 110. The barrier layer 10br prevents foreign matter from being introduced. The barrier layer 10br may include at least one inorganic layer. The barrier layer 10br may include a silicon oxide layer and a silicon nitride layer. A plurality of silicon oxide layers and a plurality of silicon nitride layers may be provided. The silicon oxide layers and the silicon nitride layers may be alternately stacked.

The barrier layer 10br may include a lower barrier layer 10br1 and an upper barrier layer 10br2. A first shielding electrode BMLa may be disposed between the lower barrier layer 10br1 and the upper barrier layer 10br2. The first shielding electrode BMLa may be disposed to correspond to the silicon transistor S-TFT. The first shielding electrode BMLa may include a metal, for example, molybdenum.

The first shielding electrode BMLa may receive a bias voltage. The first shielding electrode BMLa may receive the first power supply voltage. The first shielding electrode BMLa may block electric potential caused by polarization from affecting the silicon transistor S-TFT. The first shielding electrode BMLa may block external light from reaching the silicon transistor S-TFT. In an embodiment of the present disclosure, the first shielding electrode BMLa may be a floating electrode that is isolated from other electrodes or wiring.

A buffer layer 10bf may be disposed on the barrier layer 10br. The buffer layer 10bf may prevent metal atoms or impurities from diffusing from the base layer 110 to a first semiconductor pattern SC1 on the buffer layer 10bf. The buffer layer 10bf may include at least one inorganic layer. The buffer layer 10bf may include a silicon oxide layer and a silicon nitride layer.

The first semiconductor pattern SC1 may be disposed on the buffer layer 10bf. The first semiconductor pattern SC1 may include a silicon semiconductor. For example, the silicon semiconductor may include amorphous silicon or polycrystalline silicon. For example, the first semiconductor pattern SC1 may include low temperature poly silicon.

The first semiconductor pattern SC1 may have different electrical properties depending on whether doping is performed or not. The first semiconductor pattern SC1 may include a first area having high conductivity and a second area having low conductivity. The first area may be doped with an N-type dopant or a P-type dopant. A P-type transistor may include a doped area doped with a P-type dopant, and an N-type transistor may include a doped area doped with an N-type dopant. The second area may be a non-doped area or may be an area more lightly doped than the first area. In this embodiment, the first semiconductor pattern SC1 may be an N-type transistor.

The first area may have a higher conductivity than the second area. The first area may substantially serve as an electrode or a signal line. The second area may substantially correspond to a channel area (or, an active area) of a transistor. For example, a portion of the first semiconductor pattern SC1 may be the channel of the transistor, another portion may be a source or drain of the transistor, and the rest portion may be a connecting electrode or a connecting signal line.

The source area SE1, the channel area AC1 (or, the active area), and the drain area DE1 of the silicon transistor S-TFT may be formed from the first semiconductor pattern SC1. The source area SE1 and the drain area DE1 may extend from the channel area AC1 in opposite directions on the cross-section.

A first insulating layer 10 may be disposed on the buffer layer 10bf. The first insulating layer 10 may cover the first semiconductor pattern SC1. The first insulating layer 10 may be an inorganic layer. The first insulating layer 10 may be a single silicon oxide layer. Not only the first insulating layer 10 but also an inorganic layer of the driving element layer 120 to be described below may have a single-layer structure or a multi-layer structure and may include at least one of the aforementioned materials, but is not necessarily limited thereto.

A gate GT1 of the silicon transistor S-TFT is disposed on the first insulating layer 10. The gate GT1 may be a portion of a metal pattern. The gate GT1 may overlap the channel area AC1. The gate GT1 may be a mask in a process of doping the first semiconductor pattern SC1. A first electrode CE10 of the storage capacitor Cst may be disposed on the first insulating layer 10. Unlike that illustrated in FIG. 6, the first electrode CE10 may have a single-body shape together with the gate GT1.

A second insulating layer 10 may be disposed on the first insulating layer 20 and may cover the gate GT1. In an embodiment of the present disclosure, an upper electrode overlapping the gate GT1 may be further disposed on the second insulating layer 20. A second electrode CE20 overlapping the first electrode CE10 may be disposed on the second insulating layer 20. The upper electrode may have a single-body shape together with the second electrode CE20 when viewed from above the plane.

A second shielding electrode BMLb is disposed on the second insulating layer 20. The second shielding electrode BMLb may be disposed to correspond to the oxide transistor O-TFT. In an embodiment of the present disclosure, the second shielding electrode BMLb may be omitted. According to an embodiment of the present disclosure, the first shielding electrode BMLa may extend below the oxide transistor O-TFT to replace the second shielding electrode BMLb.

A third insulating layer 30 may be disposed on the second insulating layer 20. A second semiconductor pattern SC2 may be disposed on the third insulating layer 30. The second semiconductor pattern SC2 may include a channel area AC2 of the oxide transistor O-TFT. The second semiconductor pattern SC2 may include a metal oxide semiconductor. The second semiconductor pattern SC2 may include transparent conductive oxide (TCO) such as indium tin oxide (ITO), indium zinc oxide (IZO), indium gallium zinc oxide (IGZO), zinc oxide (ZnOₓ), or indium oxide (In₂O₃).

The metal oxide semiconductor may include a plurality of areas SE2, AC2, and DE2 distinguished from one another depending on whether the transparent conductive oxide is reduced or not. An area where the transparent conductive oxide is reduced (hereinafter, referred to as the reduced area) has a higher conductivity than an area where the transparent conductive oxide is not reduced (hereinafter, referred to as the non-reduced area). The reduced area substantially serves as a source or drain of a transistor or a signal line. The non-reduced area substantially corresponds to a semiconductor area (or, a channel) of the transistor. For example, a partial area of the second semiconductor pattern SC2 may be the semiconductor area of the transistor, another partial area may be the source area SE2 or the drain area DE2 of the transistor, and the rest portion may be a signal transmission area.

A fourth insulating layer 40 may be disposed on the third insulating layer 30. As illustrated in FIG. 6, the fourth insulating layer 40 may cover the second semiconductor pattern SC2. In an embodiment of the present disclosure, the fourth insulating layer 40 may be an insulating pattern that overlaps a gate GT2 of the oxide transistor O-TFT and exposes the source area SE2 and the drain area DE2 of the oxide transistor O-TFT.

The gate GT2 of the oxide transistor O-TFT is disposed on the fourth insulating layer 40. The gate GT2 of the oxide transistor O-TFT may be a portion of a metal pattern. The gate GT2 of the oxide transistor O-TFT overlaps the channel area AC2.

A fifth insulating layer 50 may be disposed on the fourth insulating layer 40. The fifth insulating layer 50 may cover the gate GT2. Each of the first to fifth insulating layers 10, 20, 30, 40, and 50 may be an inorganic layer.

A first connecting pattern CNP1 and a second connecting pattern CNP2 may be disposed on the fifth insulating layer 50. The first connecting pattern CNP1 and the second connecting pattern CNP2 may be formed through the same process and thus may have the same material and the same stack structure. The first connecting pattern CNP1 may be connected to the drain area DE1 of the silicon transistor S-TFT through a first pixel contact hole PCH1 penetrating the first to fifth insulating layers 10, 20, 30, 40, and 50. The second connecting pattern CNP2 may be connected to the source area SE2 of the oxide transistor O-TFT through a second pixel contact hole PCH2 that penetrates the fourth insulating layer 40 and the fifth insulating layer 50. The connection relationship between the first connecting pattern CNP1 and the silicon transistor S-TFT and the connection relationship between the second connecting pattern CNP2 and the oxide transistor O-TFT are not necessarily limited thereto.

An insulating layer 60 may be disposed on the fifth insulting layer 50. A third connecting pattern CNP3 may be disposed on the insulating layer 60. The third connecting pattern CNP3 may be connected to the first connecting pattern CNP1 through a third pixel contact hole PCH3 that penetrates the insulating layer 60. A data line DL may be disposed on the insulating layer 60. An upper insulating layer 70 may be disposed on the insulating layer 60 and may cover the third connecting pattern CNP3 and the data line DL. The third connecting pattern CNP3 and the data line DL may be formed through the same process and thus may have the same material and the same stack structure. Each of the insulating layer 60 and the upper insulating layer 70 may be an organic layer.

The first shielding electrode BMLa, the gate GT1 of the silicon transistor S-TFT, the second electrode CE20, and the gate GT2 of the oxide transistor O-TFT may include molybdenum (Mo), an alloy containing molybdenum, titanium (Ti), or an alloy containing titanium, which has good heat resistance. The first connecting pattern CNP1 and the second connecting pattern CNP2 may include aluminum having high electrical conductivity. The first connecting pattern CNP1 and the second connecting pattern CNP2 may have a three-layer structure of titanium/aluminum/titanium.

The light emitting element LD may include an anode AE (or, a first electrode), a light emitting layer EL, and a cathode CE (or, a second electrode). The anode AE of the light emitting element LD may be disposed on the upper insulating layer 70. The anode AE may be a (semi-) transmissive electrode or a reflective electrode. The anode AE may include a stack structure of ITO/Ag/ITO that are sequentially stacked one above another. The positions of the anode AE and the cathode CE may be interchanged.

A pixel defining layer PDL may be disposed on the upper insulating layer 70. The pixel defining film PDL may be an organic layer. The pixel defining layer PDL may have a property of absorbing light. For example, the pixel defining layer PDL may be black in color. The pixel defining film PDL may include a black coloring agent. The black coloring agent may include a black dye or a black pigment. The black coloring agent may include carbon black, metal such as chromium, or oxide thereof. The pixel defining layer PDL may correspond to a light blocking pattern having light blocking characteristics.

The pixel defining layer PDL may cover a portion of the anode AE. For example, an opening PDL-OP exposing a portion of the anode AE may be defined in the pixel defining layer PDL. A light emitting area LA may be defined to correspond to the opening PDL-OP. In an embodiment of the present disclosure, a hole control layer may be disposed between the anode AE and the light emitting layer EL. The hole control layer may include a hole transport layer and may further include a hole injection layer. An electron control layer may be disposed between the light emitting layer EL and the cathode CE. The electron control layer may include an electron transport layer and may further include an electron injection layer.

An encapsulation layer 140 may cover the light emitting element LD. The encapsulation layer 140 may include an inorganic encapsulation layer 141, an organic encapsulation layer 142, and an inorganic encapsulation layer 143 sequentially stacked one above another. However, layers constituting the encapsulation layer 140 are not necessarily limited thereto. The inorganic encapsulation layers 141 and 143 may include a silicon nitride layer, a silicon oxy nitride layer, a silicon oxide layer, a titanium oxide layer, or an aluminum oxide layer. Each of the inorganic encapsulation layers 141 and 143 may have a multi-layer structure. The organic encapsulation layer 142 may include an acrylic organic layer, but is not necessarily limited thereto.

The input sensing layer ISL may include at least one conductive layer (or, at least one sensor conductive layer) and at least one insulating layer (or, at least one sensor insulating layer). In this embodiment, the input sensing layer ISL may include a first insulating layer 210 (or, a first sensor insulating layer), a first conductive layer 220, a second insulating layer 230 (or, a second sensor insulating layer), a second conductive layer 240, and a third insulating layer 250 (or, a third sensor insulating layer). In FIG. 6, a conductive line of the first conductive layer 220 and a conductive line of the second conductive layer 240 are schematically illustrated.

The first insulating layer 210 may be directly disposed on the display panel DP. The first insulating layer 210 may be an inorganic layer including at least one of silicon nitride, silicon oxy nitride, and silicon oxide. Each of the first conductive layer 220 and the second conductive layer 240 may have a single-layer structure or may have a multi-layer structure stacked in the third direction DR3. The first conductive layer 220 and the second conductive layer 240 may include conductive lines that define an electrode having a mesh shape. The conductive line of the first conductive layer 220 and the conductive line of the second conductive layer 240 may be connected through a contact hole penetrating the second insulating layer 230 or might not be connected. The connection relationship between the conductive line of the first conductive layer 220 and the conductive line of the second conductive layer 240 may be determined depending on the type of sensor that forms the input sensing layer ISL.

The first conductive layer 220 and the second conductive layer 240 that have a single-layer structure may include a metal layer or a transparent conductive layer. The metal layer may include molybdenum, silver, titanium, copper, aluminum, or an alloy thereof. The transparent conductive layer may include transparent conductive oxide such as indium tin oxide (ITO), indium zinc oxide (IZO), zinc oxide (ZnOₓ), or indium zinc tin oxide (IZTO). In addition, the transparent conductive layer may include a conductive polymer, such as PEDOT, a metal nano wire, or graphene.

The first conductive layer 220 and the second conductive layer 240 that have a multi-layer structure may include metal layers. The metal layers may have, for example, a three-layer structure of titanium/aluminum/titanium. The conductive layer having the multi-layer structure may include at least one metal layer and at least one transparent conductive layer. The second insulating layer 230 may be disposed between the first conductive layer 220 and the second conductive layer 240. The third insulating layer 250 may cover the second conductive layer 240. In an embodiment of the present disclosure, the third insulating layer 250 may be omitted. The second insulating layer 230 and the third insulating layer 250 may include an inorganic layer or an organic layer.

Thus, the layered structure of the display module may include a flexible base layer, a circuit layer with driving elements, a light emitting layer, and an encapsulation layer for protection. The module may integrate both silicon and oxide transistors, various insulating and connecting layers, and a pixel architecture may include electrodes, a light emitting layer, and a pixel defining layer to control light emission. An input sensing layer with conductive and insulating films may be added, enabling capacitive or inductive touch input while maintaining transparency and durability.

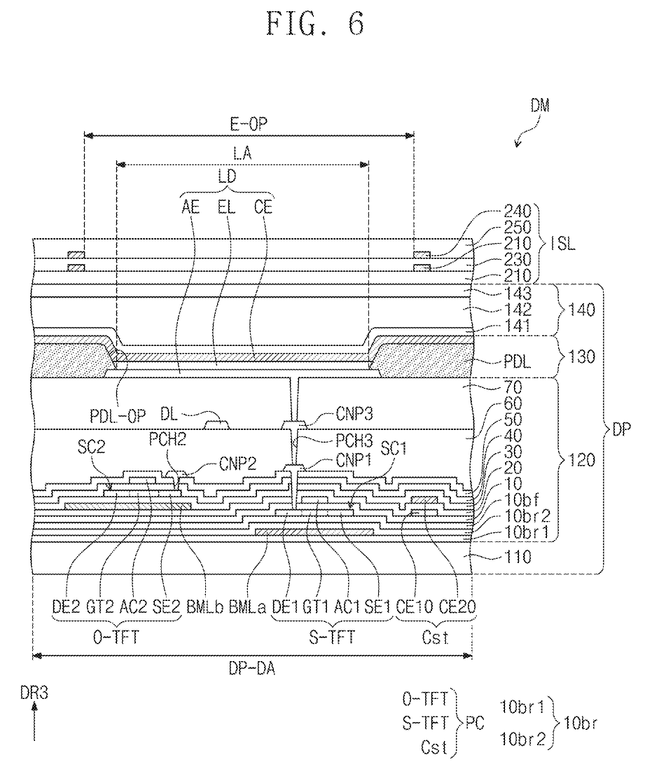

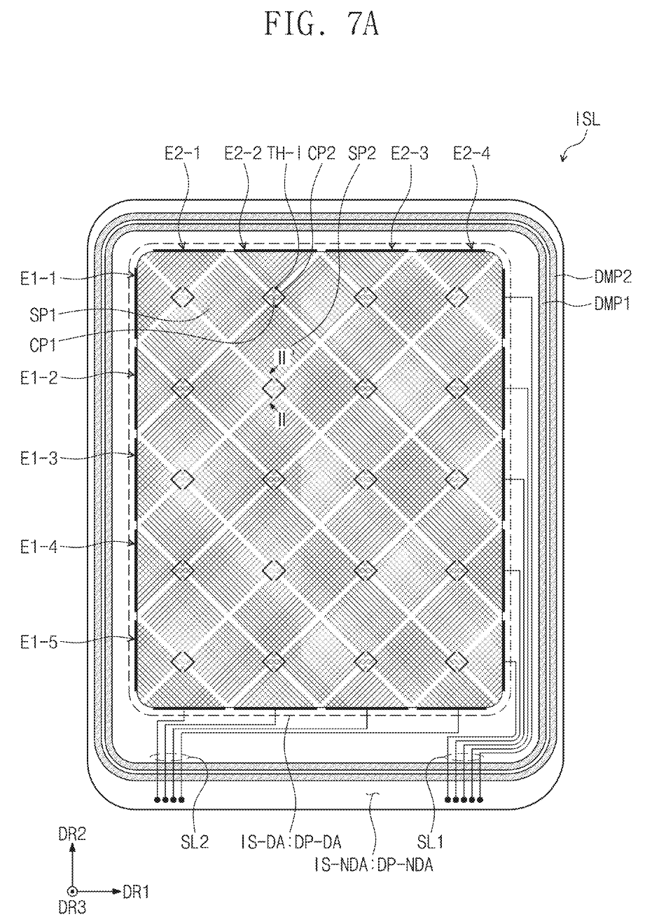

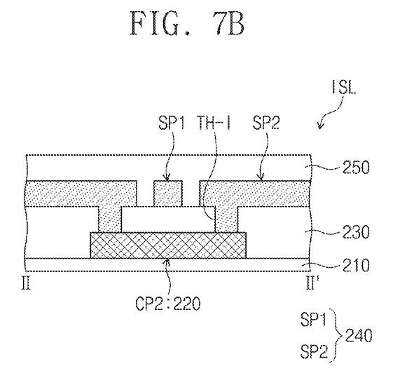

FIG. 7A is a plan view of the input sensing layer according to an embodiment of the present disclosure. FIG. 7B is a cross-sectional view of the input sensing layer taken along line II-II’ of FIG. 7A.

As illustrated in FIG. 7A, the input sensing layer ISL includes a sensing area IS-DA and a non-sensing area IS-NDA adjacent to the sensing area IS-DA. The sensing area IS-DA and the non-sensing area IS-NDA correspond to the display area DP-DA and the non-display area DP-NDA, respectively, which are illustrated in FIG. 5. The input sensing layer ISL includes first electrodes E1-1 to E1-5 (or, first sensing electrodes), second electrodes E2-1 to E2-4 (or, second sensing electrodes), first signal lines SL1 (or, first sensor signal lines), and second signal lines SL2 (or, second sensor signal lines). The first insulating pattern DMP1 and the second insulating pattern DMP2 are additionally illustrated in FIG. 7A to represent the positions of the first insulating pattern DMP1 and the second insulating pattern DMP2 relative to the input sensing layer ISL.

The first electrodes E1-1 to E1-5 and the second electrodes E2-1 to E2-4 that are insulated from each other and that cross each other are disposed in the sensing area IS-DA. The first signal lines SL1 connected to the first electrodes E1-1 to E1-5 and the second signal lines SL2 electrically connected to the second electrodes E2-1 to E2-4 are disposed in the non-sensing area IS-NDA. Either the first signal lines SL1 or the second signal lines SL2 transfer, to corresponding electrodes, a driving signal for sensing an external input from an external circuit, and the other signal lines output a sensing signal. A change in capacitance between the first electrodes E1-1 to E1-5 and the second electrodes E2-1 to E2-4 is measured based on the sensing signal. Although the input sensing layer of a mutual-cap type is illustrated as an example in this embodiment, the present disclosure is not necessarily limited thereto. An input sensing layer of a self-cap type may be applied. The input sensing layer of the self-cap type may include one type of sensing electrodes.

Each of the first electrodes E1-1 to E1-5 and the second electrodes E2-1 to E2-4 may have a mesh shape in which a plurality of openings are defined. The plurality of openings may be defined to correspond to the light emitting area LA (refer to FIG. 6) of the display panel DP. In FIG. 6, an opening E-OP corresponding to one light emitting area is illustrated. The second electrodes E2-1 to E2-4 are insulated from the first electrodes E1-1 to E1-5 and cross the first electrodes E1-1 to E1-5. Either the first electrodes E1-1 to E1-5 or the second electrodes E2-1 to E2-4 may have a single-body shape. In this embodiment, the first electrodes E1-1 to E1-5 having a single-body shape are illustrated as an example. The first electrodes E1-1 to E1-5 may include sensing portion SP1 and intermediate portions CP1.

Each of the second electrodes E2-1 to E2-4 may include sensing patterns SP2 and bridge patterns CP2 (or, connecting patterns). Two adjacent sensing patterns SP2 may be connected by two bridge patterns CP2, but the number of bridge patterns is not necessarily limited.

Referring to FIGS. 6-7B, the bridge patterns CP2 may be formed from the first conductive layer 220, and the plurality of first electrodes E1-1 to E1-5 and the sensing patterns SP2 may be formed from the second conductive layer 240. The bridge pattern CP2 may be connected to the sensing patterns SP2 through a contact hole TH-I formed in the second insulating layer 230.

In this embodiment, each of the first signal lines SL1 and the second signal lines SL2 of FIG. 7A may be formed from the first conductive layer 220 of FIG. 6. Accordingly, each of the first signal lines SL1 and the second signal lines SL2 of FIG. 7A may be disposed on the same layer as the bridge pattern CP2 of FIG. 7B. However, without being limited thereto, each of the first signal lines SL1 and the second signal lines SL2 may be formed from the second conductive layer 240. Each of the first signal lines SL1 and the second signal lines SL2 may include both a line formed from the first conductive layer 220 and a line formed from the second conductive layer 240.

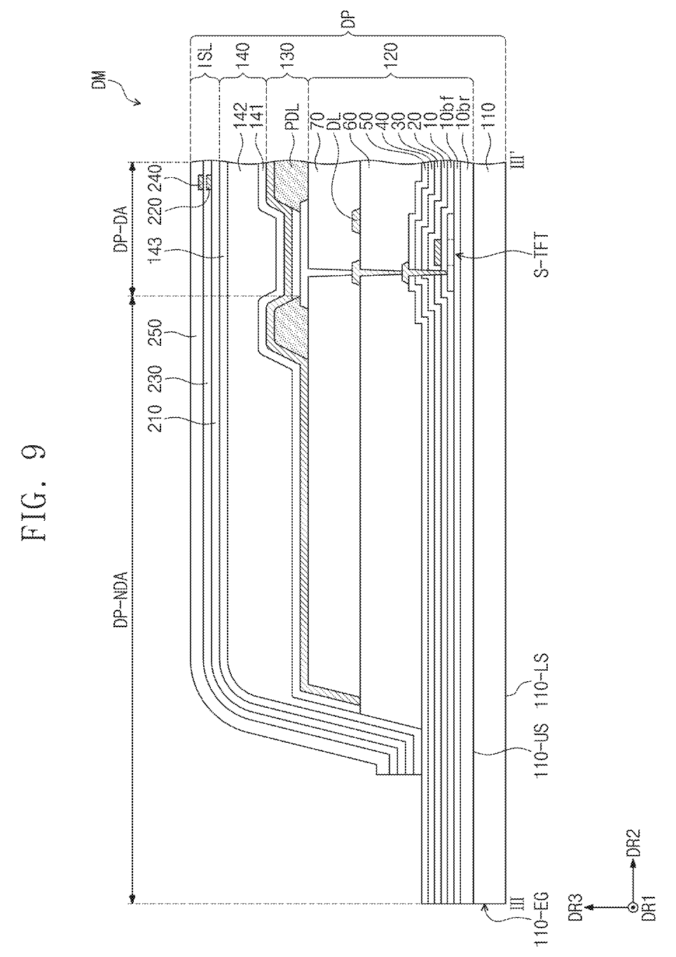

FIG. 8 is an enlarged plan view of a portion of the display module according to an embodiment of the present disclosure. For example, FIG. 8 is an enlarged plan view of the non-display area DP-NDA of the display module DM. FIG. 9 is a cross-sectional view of the display module taken along line III-III’ of FIG. 8. For example, FIG. 9 illustrates the cross-sectional structure of the non-display area DP-NDA of the display module DM corresponding to line III-III’ of FIG. 8.

As illustrated in FIGS. 8 and 9, a display area DP-DA and a non-display area DP-NDA of the display module DM are assigned with the same reference numerals as the display area DP-DA and the non-display area DP-NDA of the display panel DP of FIG. 5. In addition, the display area DP-DA and the non-display area DP-NDA may correspond to the sensing area IS-DA and the non-sensing area IS-NDA of FIG. 7A, respectively. Among the first electrodes E1-1 to E1-5 and the second electrodes E2-1 to E2-4 illustrated in FIG. 7A, the first electrode E1-5 and the second electrodes E2-1 to E2-3 are illustrated in the display area DP-DA of FIG. 8, and it may be understood that the configuration of the display panel DP in the display area DP-DA is at least similar to as described above.

FIG. 8 illustrates an enlarged view of one corner area CA (or, a vertex area) and a portion of the non-display area DP-NDA, which is disposed on the lower side of the display area DP-DA when viewed from above the plane, based on FIGS. 5 and 7A. Among the plurality of components illustrated in FIG. 8, components overlapping each other are components disposed on different layers.

The first power line PL1 and the second power line PL2 are disposed in the non-display area DP-NDA. The first power line PL1 may extend to the left non-display area DP-NDA illustrated in FIG. 5 through the corner area CA. The boundary line between the display area DA and the non-display area DP-NDA in the corner area CA may substantially have a curved line when viewed from above the plane. In FIG. 8, the boundary line between the display area DA and the non-display area DP-NDA is illustrated by a dotted line.

The first power line PL1 may pass through the left non-display area DP-NDA illustrated in FIG. 5 and may extend to the upper non-display area DP-NDA and the right non-display area DP-NDA. The second power line PL2, when viewed from above the plane, may be disposed in the non-display area DP-NDA disposed on the lower side of the display area DP-DA and may extend in the first direction DR1. The first power line PL1 and the second power line PL2 may be disposed on the same layer as the third connecting pattern CNP3 illustrated in FIG. 6.

A first voltage line VL1 and a second voltage line VL2 are disposed in the non-display area DP-NDA. Although one first voltage line VL1 and one second voltage line VL2 are illustrated, the present disclosure is not necessarily limited thereto, and a plurality of first voltage lines VL1 and a plurality of second voltage lines VL2 may be provided. The first voltage line VL1 may receive a first voltage, and the second voltage line VL2 may receive a second voltage higher than the first voltage. In an embodiment of the present disclosure, the first voltage may be the first power supply voltage, and the second voltage may be the second power supply voltage.

The first voltage line VL1 and the second voltage line VL2 do not overlap the second power line PL2 and are disposed below the second power line PL2 when viewed from above the plane. An edge EG of the display module DM may be an edge 110-EG of the base layer 110 illustrated in FIG. 9. The edge 110-EG of the base layer 110 refers to a state in which the side surface of the base layer is viewed from above the plane. The first power line PL1 and the second power line PL2 may be disposed on the same layer as the third connecting pattern CNP3 illustrated in FIG. 6 or may be disposed on the same layer as the first connecting pattern CNP1.

At least one control signal line CSL is disposed in the non-display area DP-NDA. The control signal line CSL may be connected to the scan driver circuit SDC illustrated in FIG. 5 through the corner area CA. The control signal line CSL may overlap the first power line PL1 and the second power line PL2. The control signal line CSL may be disposed on the same layer as one of the first shielding electrode BMLa, the gate GT1 of the silicon transistor S-TFT, the second electrode CE20, and the gate GT2 of the oxide transistor O-TFT illustrated in FIG. 6.

The data lines DL are disposed in the display area DP-DA and the non-display area DP-NDA. Portions of the data lines DL that overlap the display area DP-DA may be disposed on the same layer as one of the first connecting pattern CNP1 and the third connecting pattern CNP3 illustrated in FIG. 6. Portions of the data lines DL that overlap the non-display area DP-NDA may be disposed on the same layer as one of the first shielding electrode BMLa, the gate GT1 of the silicon transistor S-TFT, the second electrode CE20, and the gate GT2 of the oxide transistor O-TFT illustrated in FIG. 6. The portions of the data lines DL that overlap the display area DP-DA and the portions of the data lines DL that overlap the non-display area DP-NDA may be connected through contact holes that penetrate the barrier layer 10br, the buffer layer 10bf, and a corresponding one of the insulating layers 10 to 70 illustrated in FIG. 6. The connection points between the portions of the data lines DL that overlap the display area DP-DA and the portions of the data lines DL that overlap the non-display area DP-NDA may be located in the non-display area DP-NDA adjacent to the boundary line between the display area DP-DA and the non-display area DP-NDA.

The data lines DL may cross the first voltage line VL1, the second voltage line VL2, and the second power line PL2. An electrostatic discharge protection circuit ESD connected to the data line DL, the first voltage line VL1, and the second voltage line VL2 is disposed in the non-display area DP-NDA. The electrostatic discharge protection circuit ESD may be disposed between the first voltage line VL1 and the second voltage line VL2. In FIG. 8, one electrostatic discharge protection circuit ESD is illustrated as an example. However, without necessarily being limited thereto, an electrostatic discharge protection circuit ESD may be connected to each data line DL, or a plurality of electrostatic discharge protection circuits ESD may be connected to the respective data lines DL.

The second signal lines SL2 are disposed in the non-display area DP-NDA. The second signal lines SL2 may overlap the control signal line CSL and may overlap the first power line PL1 or the second power line PL2. Each of the second signal lines SL2 may be connected to a corresponding electrode among the second electrodes E2-1 to E2-3 disposed in the display area DP-DA.

In FIG. 8, an alignment mark AM disposed in the corner area CA is illustrated as an example. The alignment mark AM may be used as a reference point for alignment of the display module DM and a mask in a deposition process.

Referring to FIG. 9, the structure of the base layer 110, the driving element layer 120, the light emitting element layer 130, the encapsulation layer 140, and the input sensing layer ISL disposed in the display area DP-DA is the same as the configuration described with reference to FIG. 6, and to the extent that an element is not described in detail with respect to this figure, it may be understood that the element is at least similar to a corresponding element that has been described elsewhere within the present disclosure. In FIG. 9, the silicon transistor S-TFT of the pixel driving circuit PC of FIG. 6 is schematically illustrated. Each of the barrier layer 10br, the buffer layer 10bf, the insulating layers 10 to 70, and the pixel defining layer PDL described with reference to FIG. 6 may extend from the display area DP-DA to the non-display area DP-NDA. The extended shape may vary depending on layers among the barrier layer 10br, the buffer layer 10bf, the insulating layers 10 to 50, and the pixel defining layer PDL. Each of the insulating layer 60, the upper insulating layer 70, the encapsulation layer 140, the first insulating layer 210, the second insulating layer 230, and the third insulating layer 250 described with reference to FIG. 6 may extend from the display area DP-DA to the non-display area DP-NDA. The extended shape may vary depending on layers among the insulating layer 60, the upper insulating layer 70, the encapsulation layer 140, the first insulating layer 210, the second insulating layer 230, and the third insulating layer 250. Each of the insulating layer 60, the upper insulating layer 70, the encapsulation layer 140, the first insulating layer 210, the second insulating layer 230, and the third insulating layer 250 may be disposed in a portion of the non-display area DP-NDA.

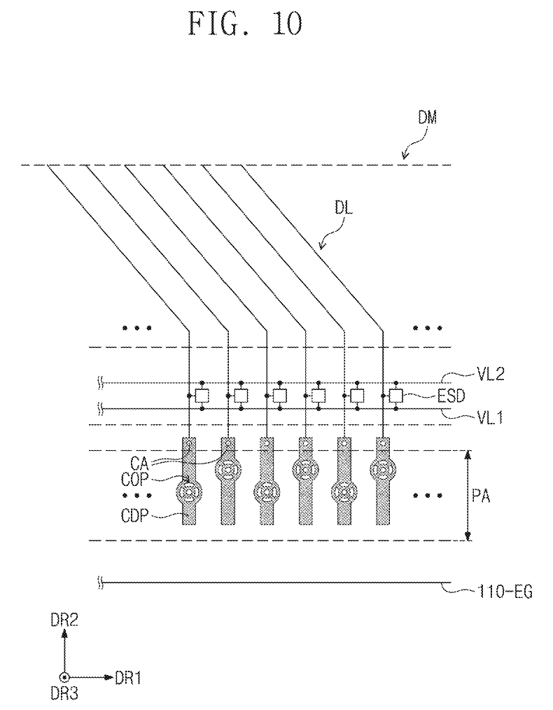

FIG. 10 is an enlarged plan view of the non-display area of the display module according to an embodiment of the present disclosure. FIG. 10 is an enlarged view of the display area DP-DA illustrated in FIG. 8. In FIG. 10, some of the data lines DL are illustrated.

Referring to FIG. 10, the first voltage line VL1 and the second voltage line VL2 may be disposed. A plurality of electrostatic discharge protection circuits ESD may be disposed between the first voltage line VL1 and the second voltage line VL2 so as to be spaced apart from one another. The electrostatic discharge protection circuit ESD may include a first transistor diode-connected from the first voltage line VL1 to the data line DL and a second transistor diode-connected from the data line DL to the second voltage line VL2.

Each of the plurality of data lines DL may be electrically connected with a conductive pattern CDP through a contact hole CA. The contact hole CA is illustrated adjacent to the first voltage line VL1, but may be differently disposed. The conductive pattern CDP may include an alloy containing molybdenum, titanium (Ti), or an alloy containing titanium. In an embodiment, the conductive pattern CDP may include aluminum having high electrical conductivity. The conductive pattern CDP may have a three-layer structure of titanium/aluminum/titanium.

A plurality of conductive patterns CDP may be provided. The conductive patterns CDP may be disposed in a direction opposite to the second direction DR2 from the first voltage line VL1. The conductive patterns CDP may be disposed to correspond to the data lines DL in a one-to-one manner. The conductive patterns CDP may be alternately arranged in the first direction DR1 so as to be spaced apart from one another. The positions of the conductive patterns CDP are merely illustrative, and the positions of the conductive patterns CDP may be changed. A conductive opening COP may be defined in each of the conductive patterns CDP. Detailed description thereabout will be given below.

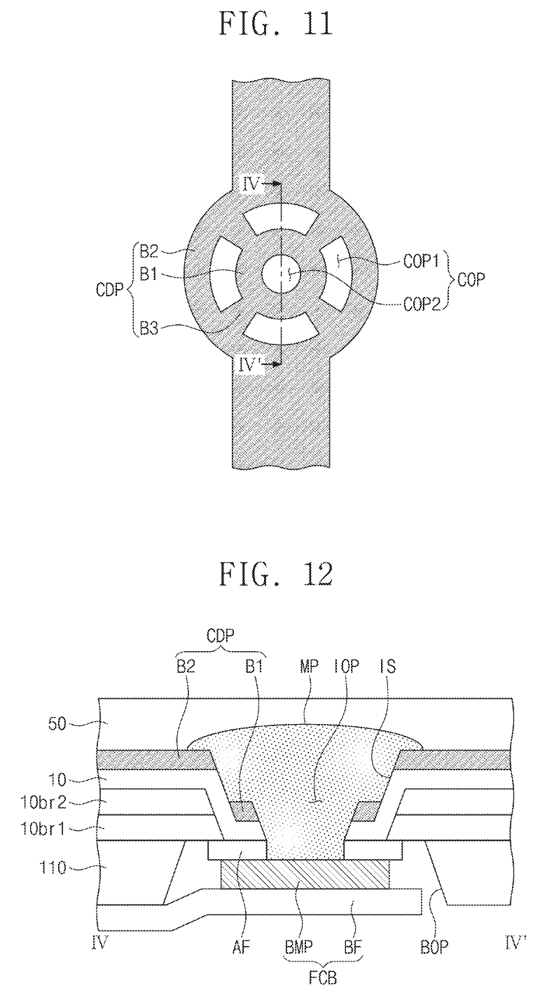

FIG. 11 is an enlarged plan view of a portion of the non-display area of FIG. 10. For example, FIG. 11 is an enlarged plan view of the conductive pattern CDP according to an embodiment of the present disclosure. FIG. 12 is a cross-sectional view of a portion of the display panel taken along line IV-IV’ of FIG. 11. In FIG. 11, one conductive pattern CDP among the conductive patterns CDP of FIG. 10 is enlarged and illustrated on a plane. In FIG. 12, the second to fourth insulating layer 20, 30, and 40 and the upper insulating layer 70 are omitted, and the same description as that of FIG. 6 may be applied to the omitted components. In addition, repetitive descriptions identical to ones given above will be omitted.

Referring to FIG. 12, a first opening BOP may be defined in the base layer 110. The base layer 110 may include a thin glass substrate, a protective film disposed on the thin glass substrate, and an adhesive layer that couples the thin glass substrate and the protective film. A component of the circuit board FCB may be disposed in the first opening BOP. For example, the circuit board FCB may be attached to the display panel DP while being bent on the rear surface of the display panel DP (refer to FIG. 3). An adhesive layer AF may be disposed between the circuit board FCB and the lower surface of the base layer 110. The circuit board FCB may be fixed to the lower surface of the base layer 110 by the adhesive layer AF.

The circuit board FCB may include a base film BF and a bump electrode BMP disposed on the base film BF. The base film BF may have a single-body shape and may be electrically connected with the bump electrode BMP. In this case, the base film BF may include a plurality of lines inside. However, without being limited thereto, the base film BF may only be attached to the bump electrode BMP and might not be electrically connected with the bump electrode BMP. In this case, the base film BF may include a synthetic resin material, for example, polyimide. The bump electrode BMP may be disposed on the base film BF. A plurality of bump electrodes BMP may be provided.

The adhesive layer AF may be disposed between the base film BF and the lower surface of the base layer 110. According to an embodiment of the present disclosure, the adhesive layer AF may include a non-conductive material. For example, the adhesive layer AF may include a non-conductive film.

According to an embodiment of the present disclosure, a second opening IOP may be defined in the first insulating layer 10. The first insulating layer 10 may include an inner surface IS that defines the second opening IOP. The second opening IOP may overlap the conductive pattern CDP illustrated in FIG. 11. For example, the second opening IOP may overlap a portion including a round shape of the conductive pattern CDP illustrated in FIG. 11.

A metal pattern MP may be disposed in the second opening IOP. For example, the metal pattern MP may fill the second opening IOP. The metal pattern MP may be a pattern obtained by curing a metal ink. The metal pattern MP may include a solder paste. The metal pattern MP may be formed from a metal ink containing silver or copper. The metal pattern MP may be formed by photocuring the metal ink.

Referring to FIGS. 11 and 12 together, the conductive pattern CDP may include a first portion B1 that overlaps the second opening IOP, a second portion B2 that does not overlap the second opening IOP, and a third portion B3 that connects the first portion B1 and the second portion B2. As illustrated in FIG. 12, the first portion B1 may be disposed in the second opening IOP, and the second portion B2 may be disposed outside the second opening IOP. The third portion B3 may be disposed in the second opening IOP. For example, the third portion B3 may be disposed on the inner surface IS.

According to an embodiment of the present disclosure, the conductive opening COP may be defined in the conductive pattern CDP to expose at least a portion of the inner surface IS of the first insulating layer 10. The conductive opening COP may include a first conductive opening COP1 and a second conductive opening COP2. At least a portion of the inner surface IS of the first insulating layer 10 may be exposed by the first conductive opening COP1. A plurality of first conductive openings COP1 may be provided. The second conductive opening COP2 may be defined in the first portion B1. For example, the second conductive opening COP2 may be formed at the center of the conductive pattern CDP. The first conductive openings COP1 and the second conductive opening COP2 each overlap the second opening IOP. The second conductive opening COP2 may have a smaller width than the second opening IOP.

The bump electrode BMP may be electrically connected with the conductive pattern CDP. For example, the bump electrode BMP may be electrically connected with the conductive pattern CDP through the metal pattern MP. In an embodiment, the metal pattern MP may be disposed in the second opening IOP. The metal pattern MP may cover the upper surface of the first portion B1 and may cover at least a portion of the upper surface of the second portion B2. In addition, the metal pattern MP may make direct contact with the first to third portions B1 to B3. For example, the metal pattern MP may also be disposed in the first conductive opening COP1 and the second conductive opening COP2 to make direct contact with the first to third portions B1 to B3 and at least a portion of the inner surface IS of the first insulating layer 10.

The metal pattern MP may be formed through a step of photocuring the metal ink. When light is emitted from the outside to the metal ink in the second opening IOP, the light emitted to the metal ink may be reflected by the conductive pattern CDP having a three-layer structure of titanium/aluminum/titanium so that a portion of the metal ink might not be sintered. Since the conductive opening COP is defined in the conductive pattern CDP of the present disclosure, the metal ink may receive light through the conductive opening COP in the step of photocuring the metal ink, and thus the photocuring step may be efficiently performed. For example, the metal ink may be entirely sintered to form the metal pattern MP, and as a result, the display device DD (refer to FIG. 2) with improved electrical reliability may be provided.

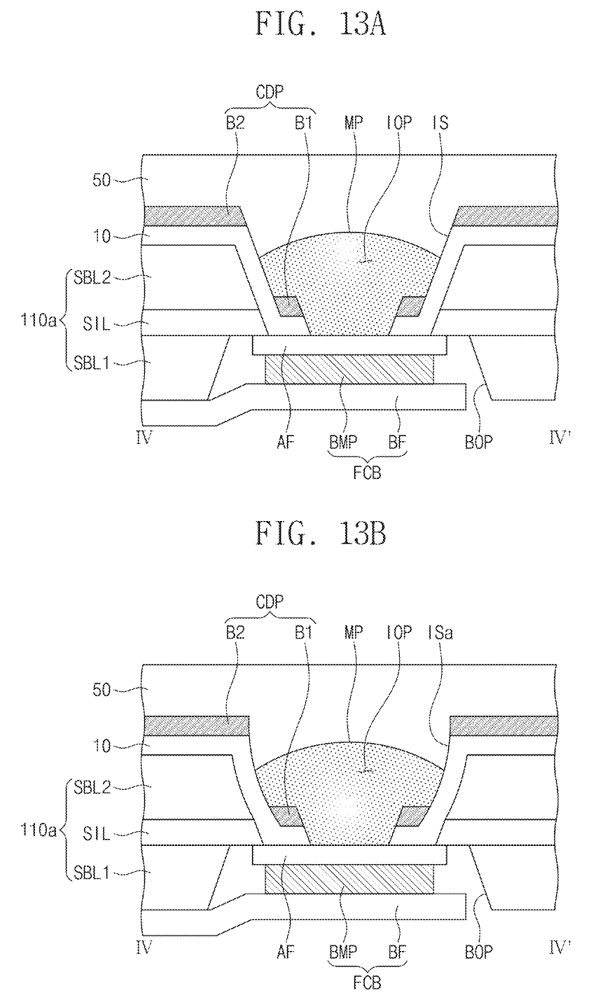

FIGS. 13A and 13B are cross-sectional views of a portion of the display panel according to embodiments of the present disclosure.

Referring to FIG. 13A, a base layer 110a may include a first sub-base layer SBL1, a sub-insulating layer SIL disposed on the first sub-base layer SBL1, and a second sub-base layer SBL2 disposed on the sub-insulating layer SIL. The first opening BOP may be defined in the first sub-base layer SBL1. Each of the first sub-base layer SBL1 and the second sub-base layer SBL2 may include the same material. For example, each of the first sub-base layer SBL1 and the second sub-base layer SBL2 may include a polyimide resin.

In FIG. 13A, the metal pattern MP may be disposed in the base layer 110a. For example, the metal pattern MP may be disposed in the second opening IOP. As illustrated in FIG. 13A, the metal pattern MP might not make contact with at least a portion of the upper surface of the second portion B2.

Referring to FIG. 13B, the first insulating layer 10 may include an inner surface ISa that defines the second opening IOP. The inner surface ISa may include a curved surface. For example, the inner surface ISa may include a curved surface recessed in the thickness direction of the base layer 110a. As a result, in the step of photocuring the metal ink to form the metal pattern MP, the optical path toward the metal ink may be shortened, and thus the metal ink may efficiently receive light through the conductive opening COP.

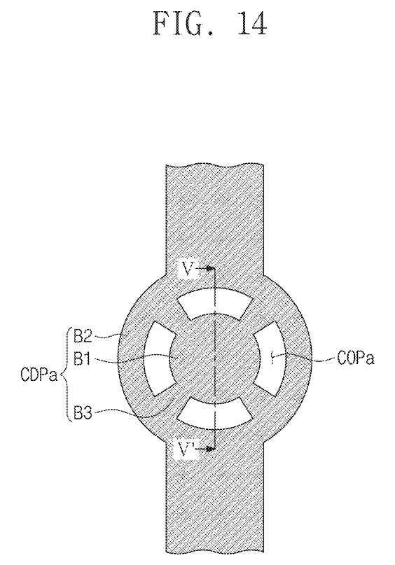

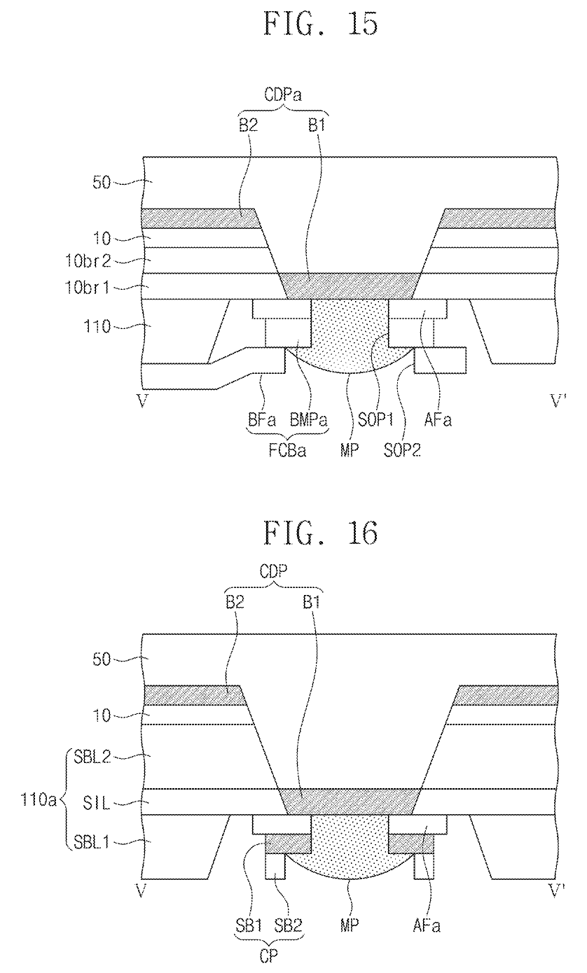

FIG. 14 is an enlarged plan view of a portion of the non-display area of FIG. 10. For example, FIG. 14 is an enlarged plan view of a conductive pattern CDPa according to an embodiment of the present disclosure. FIG. 15 is a cross-sectional view of a portion of the display panel taken along line IV-IV’ of FIG. 14.

Referring to FIG. 15, the metal pattern MP may be formed under the first portion B1. For example, the metal pattern MP may make contact with the lower surface of the first portion B1 to electrically connect a circuit board FCBa and the conductive pattern CDPa.

The circuit board FCBa may include a base film BFa and a bump electrode BMPa disposed on the base film BFa. According to an embodiment of the present disclosure, a first sub-opening SOP1 may be defined in the bump electrode BMPa, and a second sub-opening SOP2 may be defined in the base film BFa. The first sub-opening SOP1 and the second sub-opening SOP2 may overlap the first portion B1 when viewed from above the plane. In an embodiment, the second sub-opening SOP2 may have a greater width than the first sub-opening SOP1. An opening that corresponds to the first sub-opening SOP1 and the second sub-opening SOP2 may be defined in an adhesive layer AFa.

The metal pattern MP may be disposed in the first sub-opening SOP1 and the second sub-opening SOP2. The metal pattern MP may cover at least a portion of the lower surface of the bump electrode BMPa. The metal pattern MP may be disposed in the first sub-opening SOP1 and the second sub-opening SOP2 to electrically connect the circuit board FCBa and the conductive pattern CDPa.

Referring to FIGS. 14 and 15, an insulating opening COPa may be disposed on the side surface of the first insulating layer 10 and the side surface of the upper barrier layer 10br2. The insulating opening COPa might not be formed at the center of the conductive pattern CDPa. However, the present disclosure is not necessarily limited thereto, and the insulating opening COPa may be formed at the center of the conductive pattern CDPa, like the second opening COP2 illustrated in FIG. 12. In this case, the insulating opening COPa may have a smaller width than the first sub-opening SOP1.

FIG. 16 is a cross-sectional view of a portion of the display panel according to an embodiment of the present disclosure.

Referring to FIG. 16, a connecting portion CP electrically connected with the circuit board FCB (refer to FIG. 12) may be disposed under the adhesive layer AFa. The connecting portion CP may include a first sub-portion SB1 and a second sub-portion SB2. The first sub-portion SB1 may include the same material as the conductive pattern CDP, and the second sub-portion SB2 may include the same material as the first insulating layer 10. The first sub-portion SB1 may be referred to as a sub-conductive pattern. The first sub-portion SB1 may be electrically connected with the base film BFa of the circuit board FCBa illustrated in FIG. 15. For example, the base film BFa of the circuit board FCBa may be electrically connected with the conductive pattern CDP through the first sub-portion SB1 and the metal pattern MP.

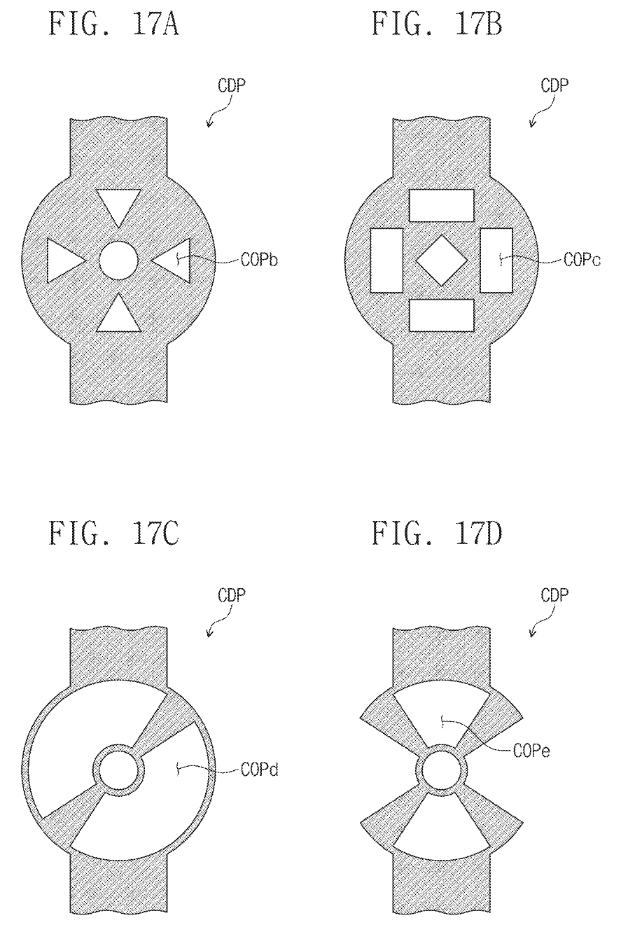

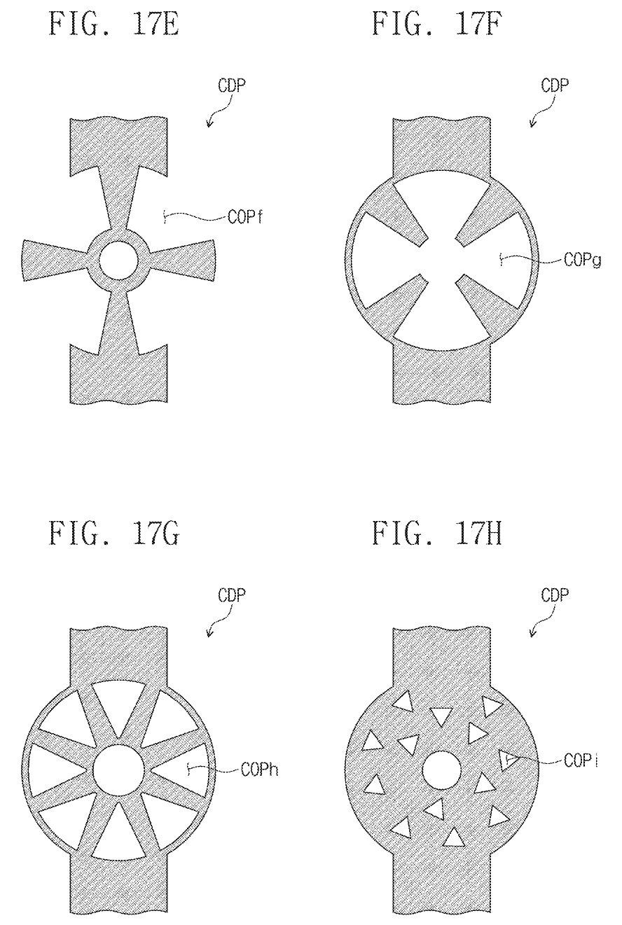

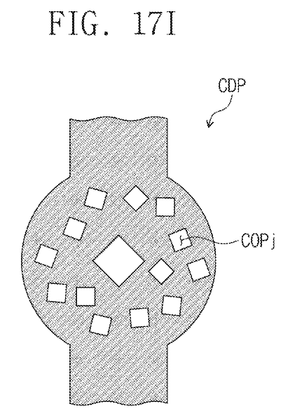

FIGS. 17A to 17E are plan views of conductive patterns according to various embodiments of the present disclosure.

Referring to FIG. 17A, a conductive opening COPb defined in a conductive pattern CDP may have a triangular shape when viewed from above the plane.

Referring to FIG. 17B, a conductive opening COPc defined in a conductive pattern CDP may have a rectangular shape when viewed from above the plane. In addition, a conductive opening COPc disposed at the center of the conductive pattern CDP may have a rhombus shape when viewed from above the plane.

Referring to FIGS. 17C and 17D, two conductive openings COPd or CDPe may be defined in a conductive pattern CDP. The conductive openings COPd or CDPe may be symmetrical to each other with respect to the center of the conductive pattern CDP.

Referring to FIG. 17E, a conductive opening COPf defined in a conductive pattern CDP may be formed through the outer surface of the conductive pattern CDP.

Referring to FIG. 17F, a conductive opening COPg defined in a conductive pattern CDP may be provided as one opening extending from the center of the conductive pattern CDP.

Referring to FIG. 17G, a plurality of conductive opening COPh may be defined in a conductive pattern CDP. As illustrated in FIG. 17G, nine conductive openings COPh may be provided.

Referring to FIGS. 17H and 17I, a plurality of conductive openings COPi or COPj defined in a conductive pattern CDP may be patterned and provided in any area.

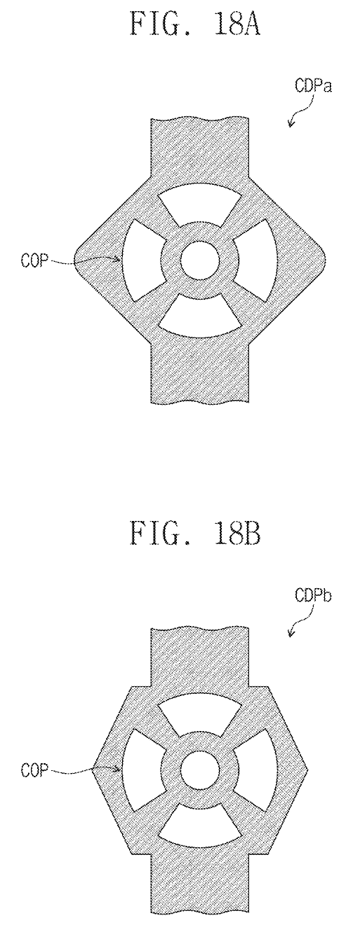

FIGS. 18A and 18B are plan views of conductive patterns according to embodiments of the present disclosure.

Referring to FIG. 18A, a portion of a conductive pattern CDPa in which a conductive opening COP is defined may have a rhombus shape when viewed from above the plane. For example, the portion of the conductive pattern CDPa in which the conductive opening COP is defined may have a quadrangular shape.

Referring to FIG. 18B, a portion of a conductive pattern CDPb in which a conductive opening COP is defined may have a polyhedral shape when viewed from above the plane. For example, the portion of the conductive pattern CDPb in which the conductive opening COP is defined may have a hexagonal shape.

Thus, according to embodiments of the present disclosure, the sensing layer may include first and second electrodes arranged in a crossing pattern, along with signal lines in the non-sensing area, to detect external inputs through capacitance changes. Conductive patterns, openings, and metal patterns may be arranged and shaped to ensure reliable electrical connections between the circuit board and the display, while enabling efficient photocuring of metal ink for strong, uniform bonding.

FIG. 19 is a block diagram of an electronic device according to an embodiment of the present disclosure.

Referring to FIG. 19, the electronic device ED, according to an embodiment of the present disclosure, may include a display module DM, a processor 12, a memory 13, and a power module 14.

The processor PC may include at least one of a central processing unit (CPU), an application processor (AP), a graphic processing unit (GPU), a communication processor (CP), an image signal processor (ISP), and a controller.

Data information required for operation of the processor PC or the display module DM may be stored in the memory MM. When the processor PC executes an application stored in the memory MM, an image data signal and/or an input control signal may be transferred to the display module DM, and the display module DM may process the provided signal and may output image information through a display screen.

The power module PM may include a power supply module such as a power adapter or a battery device and a power conversion module that converts power supplied by the power supply module and generates power required for operation of the electronic device ED.

At least one of the components of the electronic device ED described above may be included in the display device DD (refer to FIG. 2) according to the above-described embodiments. In addition, some of the separate modules functionally included in one module may be included in the display device, and the others may be provided separately from the display device DD (refer to FIG. 2). For example, the display device DD (refer to FIG. 2) may include the display module DM, and the processor PC, the memory MM, and the power module DM may be provided in the form of other devices in the electronic device ED rather than the display device DD (refer to FIG. 2).

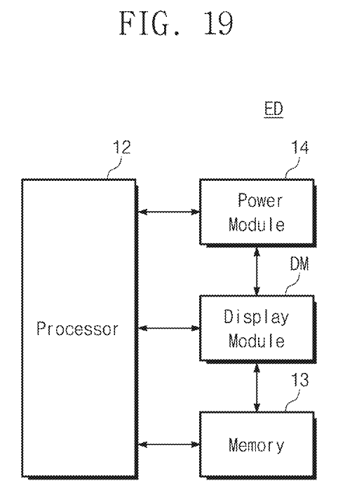

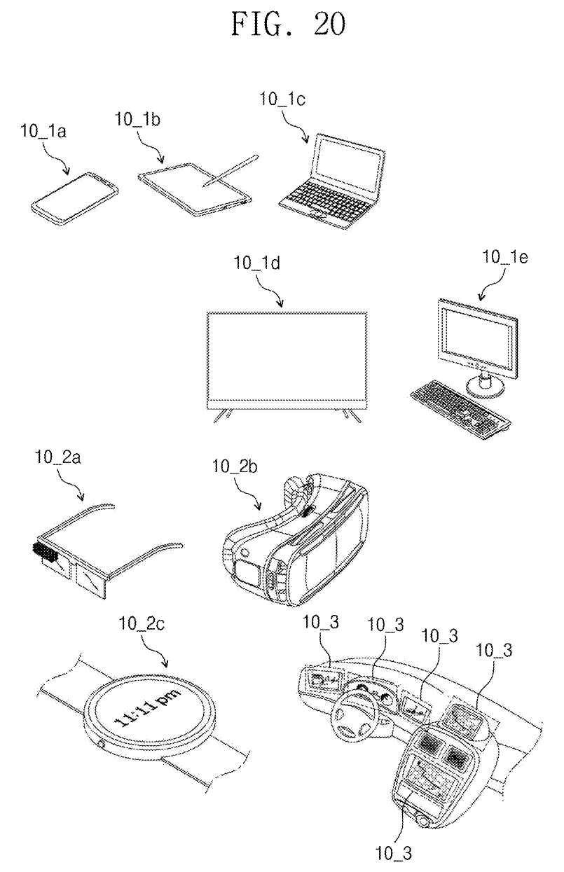

FIG. 20 illustrates schematic views of electronic devices according to various embodiments of the present disclosure.

Referring to FIG. 20, various electronic devices ED to which the display device DD (refer to FIG. 2) according to the embodiments is applied may include not only electronic devices for displaying images, such as a smart phone 10_1a, a tablet computer 10_1b, a laptop/notebook computer 10_1c, a TV 10_1d, and a computer monitor 10_1e, but also wearable electronic devices including a display module, such as smart glasses 10_2a, a head mounted display 10_2b, and a smart watch 10_2c, and vehicle electronic devices 10_3 including a display module, such as center information displays (CID) disposed on an instrument panel, a center fascia, and a dashboard of a vehicle and a room mirror display.

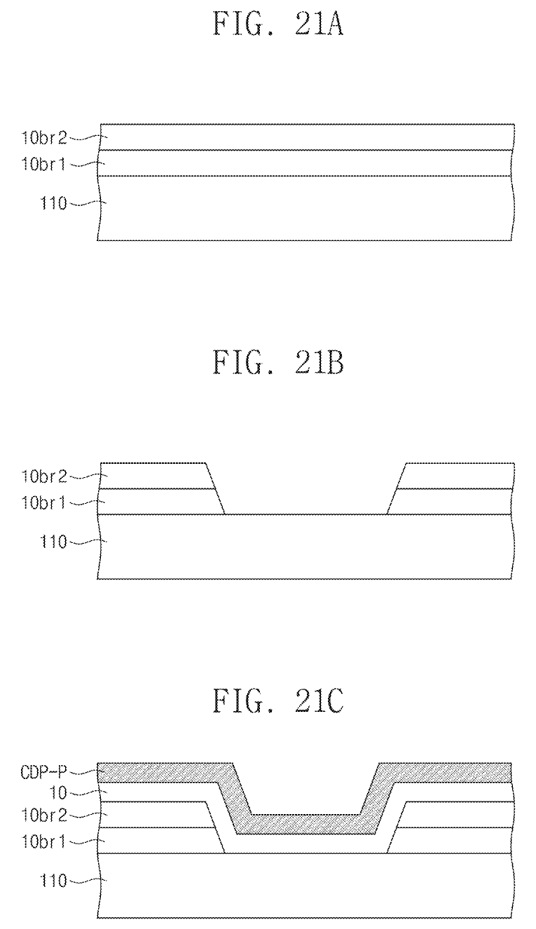

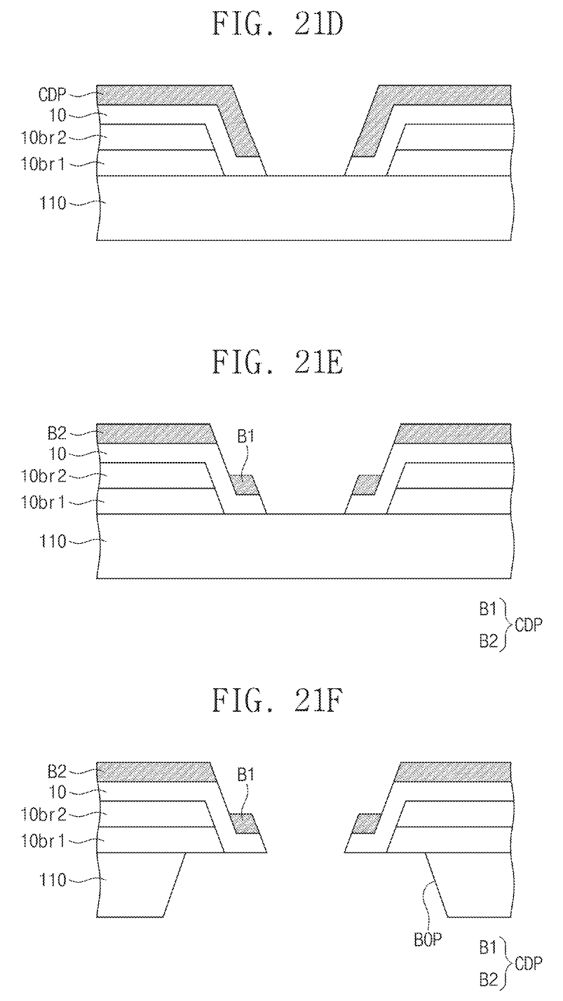

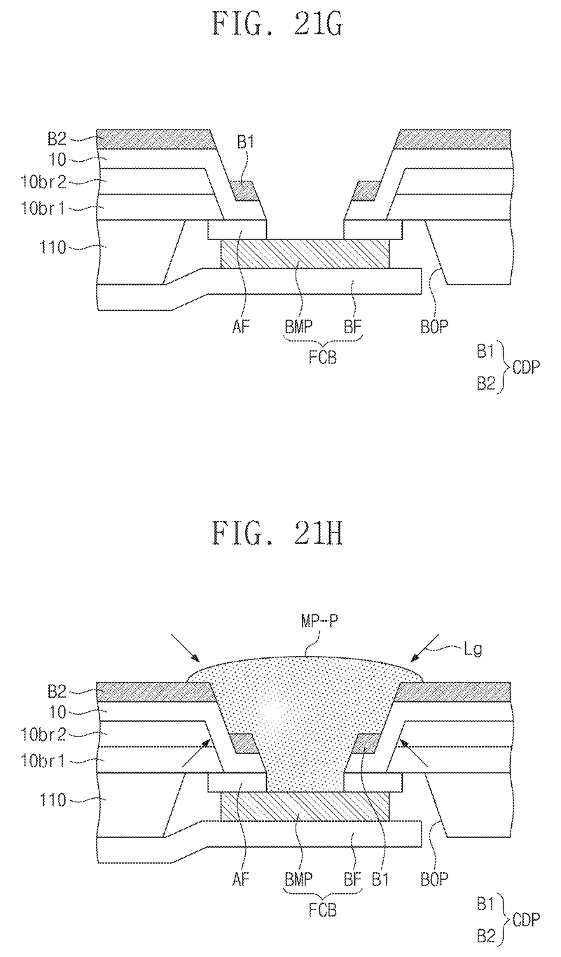

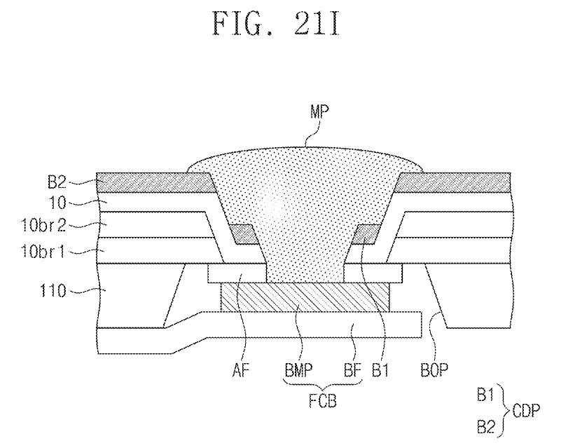

FIGS. 21A to 21I are views illustrating steps of an electronic device manufacturing method according to an embodiment of the present disclosure. In describing the electronic device manufacturing method according to an embodiment of the present disclosure with reference to FIGS. 21A to 21I, components identical to the components described above will be assigned with identical reference numerals, and to the extent that an element is not described in detail with respect to this figure, it may be understood that the element is at least similar to a corresponding element that has been described elsewhere within the present disclosure.

Referring to FIG. 21A, steps of forming the base layer 110, the lower barrier layer 10br1, and the upper barrier layer 10br2 that are sequentially stacked one above another may be performed. The steps of forming the base layer 110, the lower barrier layer 10br1, and the upper barrier layer 10br2 may be sequentially performed.

Referring to FIG. 21B, a step of etching the lower barrier layer 10br1 and the upper barrier layer 10br2 may be performed. Referring to FIG. 21C, a step of forming the first insulating layer 10 on the base layer 110, the lower barrier layer 10br1, and the upper barrier layer 10br2 and a step of forming a preliminary conductive pattern CDP-P on the first insulating layer 10 may be performed. The preliminary conductive pattern CDP-P may have a three-layer structure of titanium/aluminum/titanium.

Referring to FIG. 21D, a step of etching the preliminary conductive pattern CDP-P (refer to FIG. 21C) and the first insulating layer 10 may be performed. The conductive pattern CDP may be formed by etching the preliminary conductive pattern CDP-P (refer to FIG. 21C). In the step of etching the first insulating layer 10, the second opening IOP may be defined in the first insulating layer 10 illustrated in FIG. 12.

Referring to FIGS. 11, 12, and 21E together, a step of forming the conductive opening COP in the conductive pattern CDP may be performed. A separate mask may be used to form the conductive opening COP. The conductive opening COP may expose at least a portion of the inner surface IS of the first insulating layer 10 to the outside. In the process of forming the conductive opening COP, the conductive pattern CDP may include the first to third portions B1, B2, and B3.

Referring to FIG. 21F, a step of etching the base layer 110 may be performed. The step of etching the base layer 110 may be performed by a laser emitted from a laser device. The first opening BOP may be formed in the base layer 110 by applying the laser to the base layer 110.

Referring to FIG. 21G, a step of placing the circuit board FCB in the first opening BOP may be performed. The circuit board FCB may be disposed on the lower surface of the base layer 110. The adhesive layer AF may be disposed between the circuit board FCB and the lower surface of the base layer 110. The circuit board FCB may be fixed to the lower surface of the base layer 110 by the adhesive layer AF.

The circuit board FCB may include the base film BF and the bump electrode BMP disposed on the base film BF. The base film BF may have a single-body shape and may be electrically connected with the bump electrode BMP. The bump electrode BMP may be fixed to the lower surface of the base layer 110 by the adhesive layer AF.

Referring to FIGS. 21H and 21I together, a step of forming the metal pattern MP on the bump electrode BMP and the conductive pattern CDP may be performed. As illustrated in FIG. 21H, a preliminary metal pattern MP-P may be disposed in the second opening IOP (refer to FIG. 12). The preliminary metal pattern MP-P may be a metal ink before it is cured. A step of photocuring the preliminary metal pattern MP-P by emitting light Lg to the preliminary metal pattern MP-P may be performed. Since the conductive opening COP (refer to FIG. 11) is defined in the conductive pattern CDP of the present disclosure, the metal ink may receive light through the conductive opening COP in the step of photocuring the preliminary metal pattern MP-P, and thus the photocuring step may be efficiently performed. For example, the metal ink may be entirely sintered to form the metal pattern MP, and as a result, the display device DD (refer to FIG. 2) with improved electrical reliability may be provided. The metal pattern MP may make contact with the conductive pattern CDP and the bump electrode BMP to electrically connect the circuit board FCB and the conductive pattern CDP.

As described above, the conductive opening may be defined in the conductive pattern included in the electronic device of the present disclosure. Accordingly, the metal ink may receive light through the conductive opening in the step of photocuring the metal ink to form the metal pattern, and thus the photocuring step may be efficiently performed. As a result, the metal ink may be entirely sintered to form the metal pattern, and the electronic device with improved electrical reliability may be provided.

While the present disclosure has been described with reference to embodiments thereof, it will be apparent to those of ordinary skill in the art that various changes and modifications may be made thereto without departing from the spirit and scope of the present disclosure.

What is claimed is:

1. An electronic device, comprising:
a display panel configured to display an image;
a circuit board coupled to the display panel; and
a metal pattern electrically connecting the display panel to the circuit board,
wherein the display panel includes:
a base layer having a first opening defined therein;
an insulating layer disposed on the base layer, the insulating layer having a second opening defined therein, the second opening overlapping the first opening; and
a conductive pattern disposed on the insulating layer, the conductive pattern having a conductive opening defined therein, the conductive opening exposing at least a portion of an inner surface of the insulating layer, wherein the inner surface defines the second opening.

2. The electronic device of claim 1, wherein the metal pattern is disposed in the second opening and makes contact with the inner surface of the insulating layer.

3. The electronic device of claim 2, wherein the conductive pattern includes:
a first portion overlapping the second opening; and
a second portion that does not overlap the second opening,
wherein the metal pattern covers an upper surface of the first portion.

4. The electronic device of claim 3, wherein the conductive pattern further includes a third portion configured to connect the first portion to the second portion and disposed on the inner surface of the insulating layer, and
wherein the conductive opening is defined in the third portion.

5. The electronic device of claim 4, wherein the conductive opening includes a plurality of conductive openings, and at least one of the plurality of conductive openings is defined in the first portion.

6. The electronic device of claim 3, wherein the metal pattern covers at least a portion of an upper surface of the second portion.

7. The electronic device of claim 2, wherein a lower surface of the metal pattern makes contact with a bump electrode of the circuit board.

8. The electronic device of claim 1, wherein the conductive pattern includes:
a first portion overlapping the second opening; and
a second portion that does not to overlap the second opening,
wherein the metal pattern is disposed in the first opening and makes contact with the first portion.

9. The electronic device of claim 8, wherein the circuit board includes:
a base film; and
a bump electrode disposed between the base film and the base layer,
wherein the bump electrode and the conductive pattern are electrically connected to each other through the metal pattern.

10. The electronic device of claim 9, wherein the metal pattern is exposed by the first opening, and
wherein the metal pattern and the bump electrode are electrically connected with each other in the first opening.

11. The electronic device of claim 10, wherein a first sub-opening overlapping the first portion is defined in the bump electrode,
wherein a second sub-opening overlapping the first sub-opening is defined in the base film, and
wherein the second sub-opening has a greater width than the first sub-opening.

12. The electronic device of claim 11, wherein the metal pattern is disposed in the first sub-opening and the second sub-opening, and
wherein the metal pattern covers at least a portion of a lower surface of the bump electrode.

13. The electronic device of claim 10, further comprising:
a connecting portion including a sub-conductive pattern electrically connected to the circuit board,
wherein the conductive pattern and the sub-conductive pattern are electrically connected to one another through the metal pattern.

14. The electronic device of claim 1, further comprising:
a barrier layer disposed between the base layer and the insulating layer.

15. The electronic device of claim 1, wherein the base layer includes a first sub-base layer, a sub-insulating layer disposed on the first sub-base layer, and a second sub-base layer disposed on the sub-insulating layer, and
wherein the first opening is defined in the first sub-base layer.

16. The electronic device of claim 1, wherein the inner surface includes a curved surface recessed in a thickness direction of the base layer.

17. An electronic device, comprising:
a display panel configured to display an image;
a processor configured to provide image data to the display panel;
a circuit board coupled to the display panel;
a metal pattern electrically connecting the display panel to the circuit board;
a window disposed on the display panel; and
a housing disposed under the display panel and coupled to the window, the housing configured to accommodate the display panel and the circuit board,
wherein the display panel includes:
a base layer having a first opening defined therein;
an insulating layer disposed on the base layer, the insulating layer having a second opening defined therein overlapping the first opening; and
a conductive pattern disposed on the insulating layer, the conductive pattern having a conductive opening defined therein exposing at least a portion of an inner surface of the insulating layer, wherein the inner surface defines the second opening.

18. A method for manufacturing an electronic device, the method comprising:
forming a base layer having a first opening defined therein;
forming, on the base layer, an insulating layer having a second opening defined therein overlapping the first opening;
forming a conductive pattern on the insulating layer;
patterning the conductive pattern to form a conductive opening exposing at least a portion of an inner surface of the insulating layer, wherein the inner surface defines the second opening;
providing a bump electrode of a circuit board in the first opening; and
forming a metal pattern in the second opening,
wherein the conductive pattern is electrically connected to the bump electrode through the metal pattern.

19. The method of claim 18, wherein the patterning of the conductive pattern is performed after forming the second opening.

20. The method of claim 18, wherein in forming the metal pattern, the metal pattern makes contact with the inner surface of the insulating layer.
